(19) United States
(12) Patent Application Publication
(10) Pub. No.: US 2020/0388791 A1
(43) Pub. Date: Dec. 10, 2020

(54) ORGANIC ELECTROLUMINESCENT DEVICE CONTAINING CAPPING LAYER AND USE

(71) Applicant: VALIANT CO., LTD., Yantai (CN)

(72) Inventors: ZHAOCHAO ZHANG, WUXI (CN); CHONG LI, WUXI (CN); DANDAN TANG, WUXI (CN); LICHUN WANG, WUXI (CN)

(73) Assignee: VALIANT CO., LTD.

(21) Appl. No.: 16/907,263

(22) Filed: Jun. 21, 2020

Related U.S. Application Data
(63) Continuation of application No. PCT/CN2018/123285, filed on Dec. 25, 2018.

(30) Foreign Application Priority Data
Dec. 28, 2017 (CN) 201711460825.1

(51) Int. Cl. H01L 51/52; H01L 51/00

(52) U.S. Cl. CPC H01L 51/5275; H01L 51/0067; H01L 51/0073; H01L 51/0071; H01L 51/0072

(57) ABSTRACT

The disclosure relates to an organic electroluminescent device containing a capping layer. The organic electroluminescent device has: a substrate layer; a first electrode, the first electrode being located on the substrate; an organic light-emitting functional layer, the organic light-emitting functional layer being located on the first electrode; a second electrode, the second electrode being located on the organic light-emitting functional layer; and the capping layer, the capping layer being located on the side of the organic electroluminescent device where light is emitted, wherein the capping layer comprises an organic compound. The organic compound of the capping layer has the following properties: having a molecular weight falling within the range from 500 to 1200 and containing lone pair electrons, the number of the lone pair electrons being greater than or equal to 2. The disclosure relates to use of the organic electroluminescent device containing the capping layer for a display or lighting apparatus.

### CROSS-REFERENCE TO RELATED APPLICATIONS

This application is a continuation of International Patent Application No. PCT/CN2018/123285 with a filing date of Dec. 25, 2018, designating the United States, now pending, and claims priority to Chinese Patent Application No. 201711460825.1 with a filing date of Dec. 28, 2017. The content of the aforementioned applications, including any intervening amendments thereto, are incorporated herein by reference.

### TECHNICAL FIELD

The disclosure relates to an organic electroluminescent device, and particularly to an organic electroluminescent device which comprises a capping layer and can effectively improve light extraction efficiency.

### BACKGROUND

An organic light emission diode (OLED) device technology can be used for not only manufacturing novel display products but also preparing novel lightening products, is expected to replace the existing liquid crystal display and fluorescent lamp for lightening, and has a wide application prospect. The OLED device has a sandwich-like structure, including electrode layers and organic light-emitting functional layers clamped among different electrode layers, various electrode layers and organic light-emitting layer functional layers as well as other relevant material layers are overlapped with one another according to use to jointly constitute the OLED device. When the OLED device, as a current driving device, applies a voltage to electrodes at two ends so as to act on positive and negative charges in the organic functional material layer through an electric field, the positive and negative charges are further composited on the organic functional material layer, so as to generate OLED electroluminescence.

At present, the OLED display technology has been applied in the fields of smart phones, tablet personal computers and the like, and will be extended to large-size application fields of televisions and the like. Since there is a huge difference between external quantum efficiency and internal quantum efficiency of OLED, greatly restricting the development of OLED. Therefore, how to improve the light extraction efficiency of OLED becomes a research hotspot. Total reflection occurs at an interface between an ITO thin film and a glass substrate and at an interface between the glass substrate and air. Light emitted to the external space of the OLED device accounts for about 20% of the total amount of the organic material thin film EL, the rest about 80% of light is restricted in the organic material thin film, the ITO thin film and the glass substrate in a form of guided waves. It can be seen that the light extraction efficiency of the conventional OLED device is relatively low (about 20%), which seriously restricts development and application of OLED. Hence, how to reduce the total reflection effect in the OLED device, improve the proportion (light extraction efficiency) of light emitted to the external space prior to coupling to the device catches more people's attention.

At present, one class of important methods for improving the light extraction efficiency of OLED are to form structures such as wrinkles, photonic crystals, microlens arrays (MLA) and added space capping layers on the light outgoing surface. The former two methods can structurally influence the radiation spectrum angle distribution of OLED, and the third method is complicated in preparation process. The used surface capping layer process is simple and allows light-emitting efficiency to be improved by 30% or more, which is especially focused by people.

Therefore, for the situation that the current OLED device has low light extraction efficiency, it is hopeful to use a capping layer (light extraction material layer) in the structure, which is capable of realizing higher light extraction efficiency and it is expected to reduce the angle dependency of the device.

### SUMMARY

Aiming at the above problems existing in the prior art, the inventor of the disclosure finds that when a specific type of organic compound is used to prepare a capping layer and the capping layer is used to prepare the organic electroluminescent device, since the specific type of organic compound contains many lone pair electrons, it has extremely high polarization capability, and furthermore the specific type of organic compound and a metal electrode can be coupled into a disordered grating structure. Therefore, the organic electroluminescent device prepared by the capping layer made of the specific type of organic compound is improved in current efficiency, increased in light extraction efficiency and relieved in angle dependence. Thus, the present application uses an organic compound for the capping layer, the organic compound material can stably form a film in a certain manner to be used for preparing the organic electroluminescent device. Light-emitting angle dependence is relieved while the light extraction efficiency of the prepared OLED device is effectively improved.

It is an object of the disclosure to provide an organic electroluminescent device, the organic electroluminescent device comprising:

a substrate layer;

a first electrode, the first electrode being located on the substrate;

an organic light-emitting functional layer, the organic light-emitting functional layer being located on the first electrode;

a second electrode, the second electrode being located on the organic light-emitting functional layer; and

the capping layer, the capping layer being located on the side of the organic electroluminescent device where light is emitted,

wherein, the capping layer comprises an organic compound,

the organic compound of the capping layer has the following properties:

having a molecular weight from 500 to 1200 and containing lone pair electrons, the number of the lone pair electrons being is greater than or equal to 2.

After being applied to the OLED device, the capping layer material provided by the disclosure can improve the light extraction efficiency of the device, reduce the angle dependence and facilitate the preparation and use of the OLED device after being applied to the OLED device.

### DESCRIPTION OF THE DRAWINGS

FIG. 1 is a diagram of a cross-sectional structure of an organic electroluminescent device containing a capping layer provided by the disclosure.

FIG. 2 is a diagram of a cross-sectional structure of an organic light-emitting functional layer in the organic electroluminescent device provided by the disclosure.

FIG. 3 shows any combination of a blue organic light-emitting layer material and a green, yellow or red light-emitting layer material, regardless of sequence.

FIG. 4 shows a combination of any two of the blue organic light-emitting layer material and the green, yellow or red light-emitting layer material, regardless of sequence.

FIG. 5 shows horizontal arrangement of the blue organic light-emitting layer material, the green organic light-emitting layer material and the red organic light-emitting layer material.

FIG. 6 shows any combination of the blue organic light-emitting layer material and the green, yellow or red light-emitting layer material, and charge transport is conducted through a connection layer to form a device structure having two laminated layers.

FIG. 7 shows a combination of any two of the blue organic light-emitting layer material and green, yellow or red light-emitting layer material, and charge transport is conducted through the connecting layer to form a device structure having three laminated layers.

### DESCRIPTION OF THE EMBODIMENTS

It is an object of the disclosure to provide an organic electroluminescent device, the organic electroluminescent device comprising:

a substrate layer;

a first electrode, the first electrode being located on the substrate;

an organic light-emitting functional layer, the organic light-emitting functional layer being located on the first electrode;

a second electrode, the second electrode being located on the organic light-emitting functional layer; and

the capping layer, the capping layer being located on the side of the organic electroluminescent device where light is emitted,

wherein, the capping layer comprises an organic compound,

the organic compound of the capping layer has the following properties:

having a molecular weight from 500 to 1200 and containing lone pair electrons, the number of the lone pair electrons being greater than or equal to 2.

The organic electroluminescent device of the disclosure will be specifically illustrated from two aspects hereinafter.

In the first aspect:

The disclosure will be described in detail in combination with structural formulas and test data. It is understood that embodiments described here are only for explaining but not limiting the disclosure.

The capping layer of the organic electroluminescent device of the disclosure can be an organic material consisting of an organic compound, an inorganic material or a combination thereof.

The organic material of the capping layer of the organic electroluminescent device of the disclosure is an organic compound containing two pairs and more than two pairs of SP2 hybridized lone pair electrons. The chemical groups containing SP2 hybridized lone pair electrons can be exemplified as one or a combination of more of groups of pyridine, pyrazine, pyridazine, pyrimidine, triazine, quinoline, isoquinoline, quinoxaline, quinazoline, cinnoline, 2,3-phthalazin, naphthyridine, benzimidazole, benzoxazole, phenanthroline, azatriphenylene, indolylpyridine, acridine, pyrazole, oxadiazole, triazole, pyrazolone, imidazole, imidazolinone, ketone, ether or sulfoxide.

Preferably, the group of the organic compound of the capping layer which contains the lone pair electrons is one or more of the following groups:

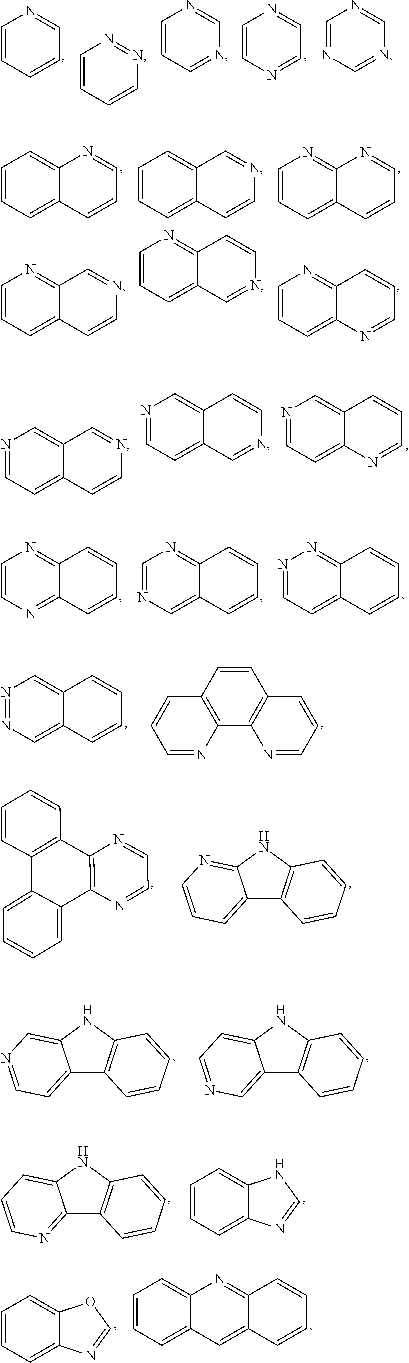

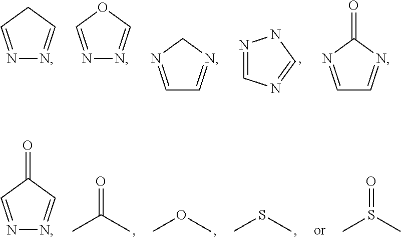

The inorganic material of the capping layer can comprise ITO, IZO, SiO₂, SiNx, Y₂O₃, WO₃, MoO₃ or Al₂O₃.

In one embodiment, the number of the lone pair electrons of the organic compound of the capping layer is 2 or more, preferably 3-15, most preferably 3-9.

In a preferred embodiment, lone pair electron-containing atoms in the organic compound of the capping layer are bonded by SP2 hybridized orbit.

In a preferred embodiment, an atom having the lone pair electrons in the organic compound of the capping layer is one or more of N, O and S atoms.

The molecular weight of the organic compound of the capping layer is 500-1100, preferably 600-1000, more preferably 600-850.

In a preferred embodiment, the refractive index of the organic compound of the capping layer is 1.7 or more within the wavelength range of 380 nm-780 nm.

In a preferred embodiment, the organic compound of the capping layer provided by the disclosure has a refractive index higher than refractive indexes of the organic light-emitting functional layer material and the first electrode and the second electrode, and is arranged near the electrode layers. Preferably, the capping layer is formed outside the electrode on the side where light is emitted. When light is injected into a layer having a high reflective index from a layer having a low reflective index, even though an incident angle is large, light is not totally reflected, and at least one part of light can be injected into the layer having the high reflective index. Therefore, in the organic electroluminescent device of the disclosure, when light is injected from the organic light-emitting functional layer having the low reflective index and the electrode layer into the capping layer having the high reflective index, light is not totally reflected on the interface between the electrode layer and the capping layer, at least one part of light can penetrate through the capping layer to be emitted to the outside, and thus the quantity of totally reflected light between interfaces of the capping layer and the electrode layers can be reduced, and the light extraction efficiency of the organic electroluminescent device is improved.

Preferably, the reflective index of the organic compound of the capping layer is 1.8 or more in the field of blue light, preferably 2.0 or more, more preferably 2.0-2.4; the reflective index of the organic compound of the capping layer is 1.8 or more in the field of green light, preferably 1.9 or more, more preferably 1.9-2.2; the reflective index of the organic compound of the capping layer is 1.7 or more in the field of red light, preferably 1.8 or more, more preferably 1.8-2.1.

Preferably, the extinction coefficient of the organic compound of the capping layer is 1.0 or less within the wavelength range of 380 nm-780 nm.

Preferably, the organic compound of the capping layer has relatively strong absorption at 310-430 nm, and has no absorption in a visible light region.

In a preferred embodiment, the organic compound of the capping layer of the disclosure has no absorption at 350±20 nm, can absorb UV irradiation in the CVD process during the encapsulation of the flexible OLED device and can reduce the damage of UV light on the OLED material.

The thickness of the capping layer of the disclosure can be 10-1000 nm, preferably 30-120 nm.

The capping layer of the disclosure can be a single layer or multiple layers. Preferably, the capping layer can be formed by using more than two materials having different reflective indexes, two layers or multiple layers are formed by alternately overlapping the material layer having relatively high reflective index and the material layer having relatively low reflective index. The multi-layer capping layer can cause constructive interference and improve light extraction efficiency.

Preferably, the capping layer of the disclosure is made of the organic compound.

Specifically, in one embodiment, the organic compound that can be used by the capping layer of the organic electroluminescent device of the disclosure has a structural formula as follows:

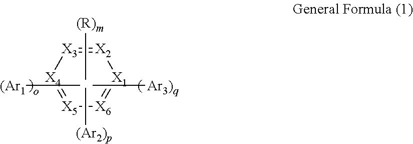

wherein, X₁˜X₆ each independently represent N atom, C atom or CH, wherein the number of N atoms is 1-4;

o, p and q independently represent the number 0, 1, 2 or 3 respectively, and 0≤o+p+q≤4;

m represents the number 0, 1, 2 or 3, and 0≤o+p+q+m≤4;

Ar₁, Ar₂ and Ar₃ are independently identical or different in each case and can be independently expressed as a structure shown in general formula (2) respectively:

—L—R₁ General formula (2)

wherein, L represents a single bond, substituted or unsubstituted C₆₋₆₀ arylidene, substituted or unsubstituted 5-60-membered heteroarylidene containing one or more heteroatoms, wherein the heteroatom is nitrogen, oxygen or sulfur;

R₁ represents one of groups of benzimidazole and derivatives, quinoxaline and derivatives, benzoxazole and derivatives, and naphthyridine and derivatives;

R represents substituted or unsubstituted C₆₋₆₀ aryl, substituted or unsubstituted 5-60-membered heteroaryl containing one or more heteroatoms, wherein the heteroatom is nitrogen, oxygen or sulfur.

In a preferred embodiment, L in general formula (2) represents phenylene, biphenylene, naphthylene, pyridinediyl or naphthylidene substituted or unsubstituted by C₁₋₁₀ linear or branched alkyl, halogen atoms, protium atom, deuterium atom or tritium atom;

R in general formula (1) represents one of phenyl substituted or unsubstituted by C₁₋₁₀ linear or branched alkyl, halogen atoms, protium atom, deuterium atom or tritium atom; naphthyl substituted or unsubstituted by C₁₋₁₀ linear or branched alkyl, halogen atoms, protium atom, deuterium atom or tritium atom; biphenyl, terphenyl or anthryl substituted or unsubstituted by C₁₋₁₀ linear or branched alkyl, halogen atoms, protium atom, deuterium atom or tritium atom; pyridyl, pyrimidinyl, pyrazinyl, pyridazinyl, dibenzofuran, 9,9-dimethylfluorene, N-phenylcarbazole, quinolinyl, isoquinolinyl or naphthyridine group substituted or unsubstituted by C₁₋₁₀ linear or branched alkyl, halogen atoms, protium atom, deuterium atom or tritium atom; R is also expressed as a structure shown in general formula (3), general formula (4) or general formula (5);

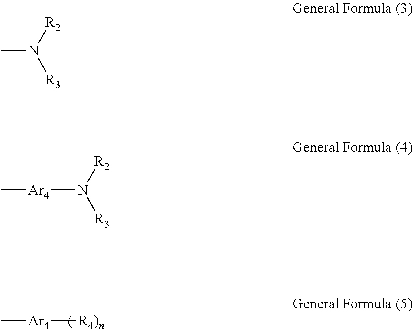

Ar₄ in general formula (4) and general formula (5) independently represents one of phenyl substituted or unsubstituted by C₁₋₁₀ linear or branched alkyl, halogen atoms, protium atom, deuterium atom or tritium atom; naphthyl substituted or unsubstituted by C₁₋₁₀ linear or branched alkyl, halogen atoms, protium atom, deuterium atom or tritium atom; biphenyl, terphenyl or anthryl substituted or unsubstituted by C₁₋₁₀ linear or branched alkyl, halogen atoms, protium atom, deuterium atom or tritium atom; pyridyl, pyrimidinyl, pyrazinyl, pyridazinyl, dibenzofuran, 9,9-dimethylfluorene, n-phenylcarbazole, quinolinyl, isoquinolinyl or naphthyridine group substituted or unsubstituted by C₁₋₁₀ linear or branched alkyl, halogen atoms, protium atom, deuterium atom or tritium atom, respectively;

in general formula (3), general formula (4) and general formula (5), R₂, R₃ and R₄ independently represent one of phenyl substituted or unsubstituted by C₁₋₁₀ linear or branched alkyl, halogen atoms, protium atom, deuterium atom or tritium atom; naphthyl substituted or unsubstituted by C₁₋₁₀ linear or branched alkyl, halogen atoms, protium atom, deuterium atom or tritium atom; spirobifluorene group substituted or unsubstituted by C₁₋₁₀ linear or branched alkyl, halogen atoms, protium atom, deuterium atom or tritium atom; biphenyl, terphenyl or anthryl substituted or unsubstituted by C₁₋₁₀ linear or branched alkyl, halogen atoms, protium atom, deuterium atom or tritium atom; pyridyl, pyrimidinyl, pyrazinyl, pyridazinyl, dibenzofuran, 9,9-dimethylfluorene, n-phenylcarbazole, quinolinyl, isoquinolinyl or naphthyridine group substituted or unsubstituted by C₁₋₁₀ linear or branched alkyl, halogen atoms, protium atom, deuterium atom or tritium atom, respectively;

R₂, R₃ and R₄ are each independently identical or different;

in general formula (5), n represents an integer 1 or 2.

More preferably, the structural formula of the organic compound that can be used by the capping layer of the organic electroluminescent device of the disclosure is as follows:

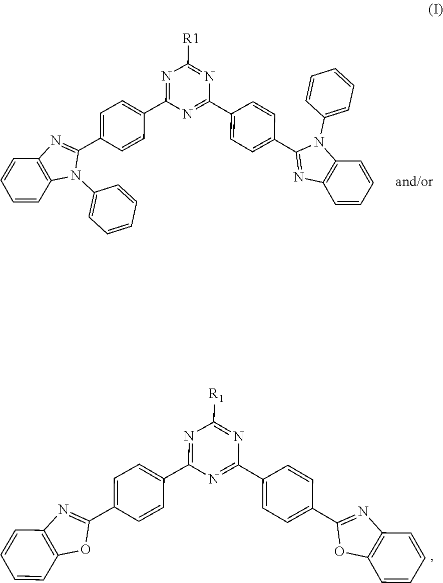

wherein R1 is selected from biphenylyl, naphtyl, biphenylyl, N-phenylcarbazolyl or

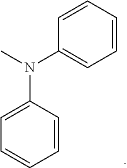

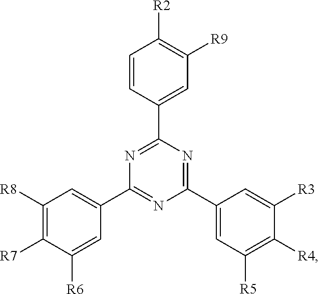

wherein R2 is selected from H, C1-6 alkyl, pyridyl, pyrimidyl,

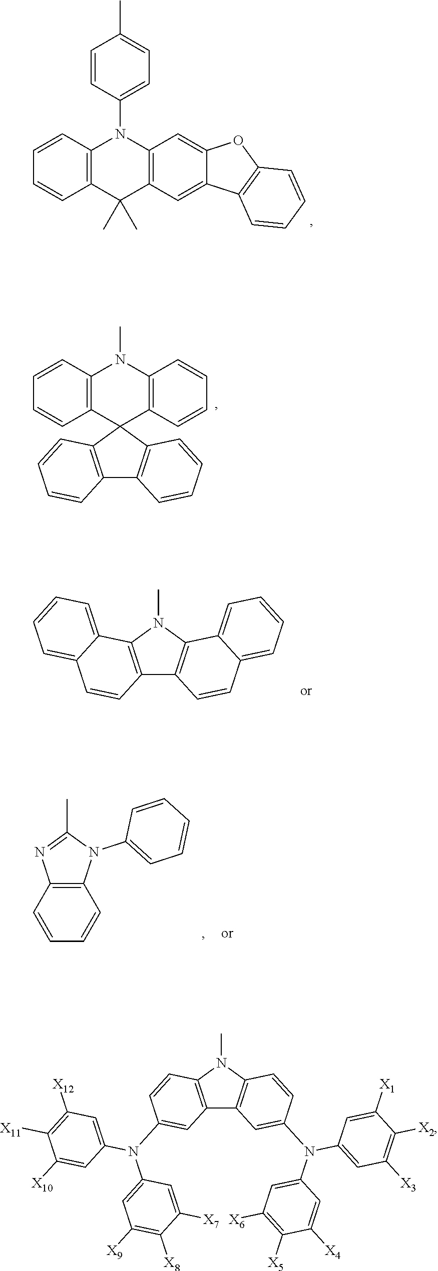

wherein X1, X2, X3, X4, X5, X6, X7, X8, X9, X10, X11 and X12 are each independently hydrogen or C1-C6 alkyl, preferably hydrogen, methyl or tert-butyl;

R3, R4, R5, R6, R7 and R8 are each independently selected from hydrogen, C1-C6 alkyl, pyridyl, pyrimidyl,

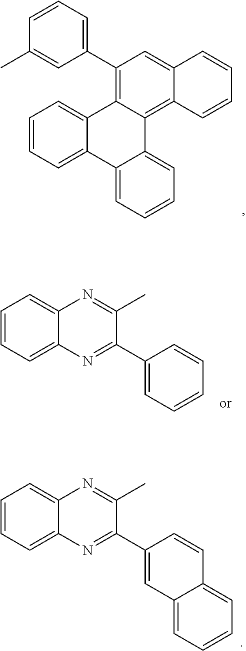

R9 is selected from H, C1-C6 alkyl, pyrimidyl, pyridyl,

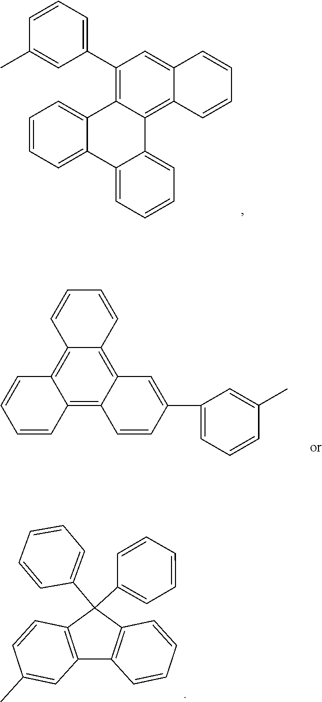

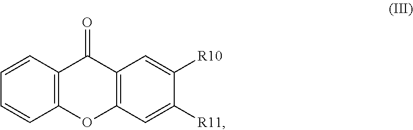

wherein R10 and R11 are each independently selected from

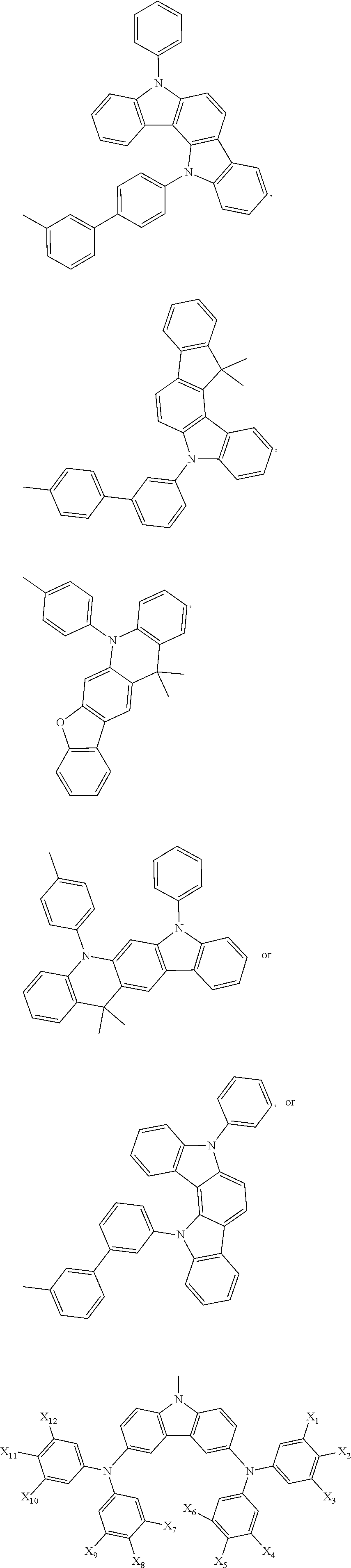

wherein, X1, X2, X3, X4, X5, X6, X7, X8, X9, X10, X11 and X12 are each independently hydrogen or C1-C6 alkyl, preferably hydrogen, methyl or tert-butyl.

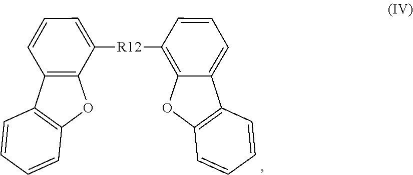

wherein R12 is selected from

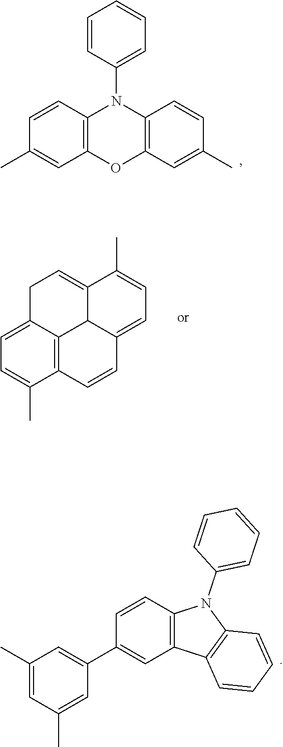

In another embodiment, a material that can be used by the capping layer of the organic electroluminescent device of the disclosure is selected from one or more of the following organic compounds:

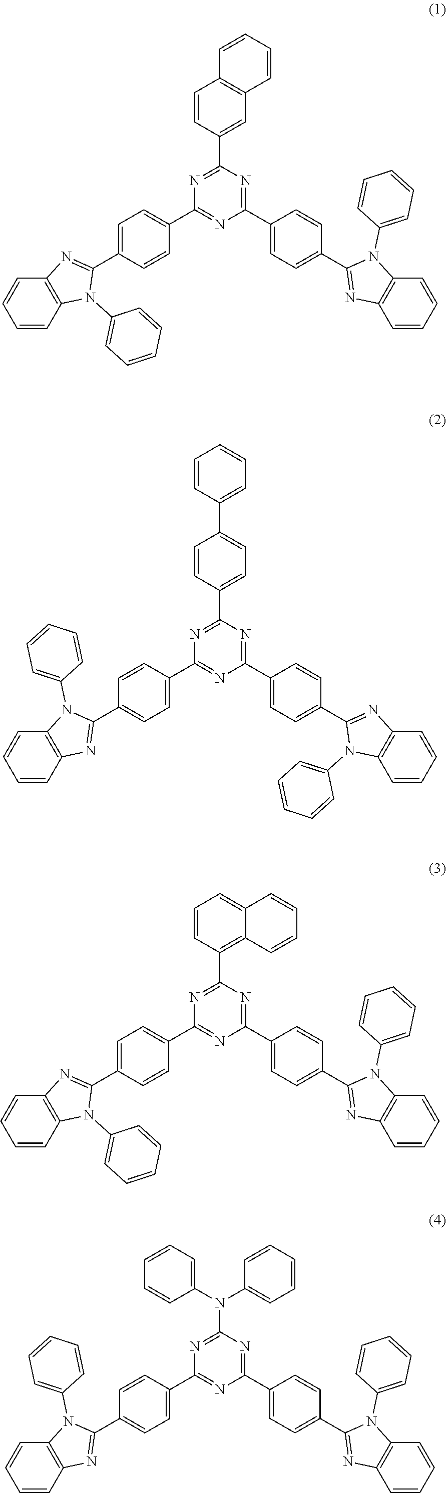 [SMILES: c1ccc(-n2c(-c3ccc(-c4nc(-c5ccc(-c6nc7ccccc7n6-c6ccccc6)cc5)nc(-c5ccc6ccccc6c5)n4)cc3)nc3ccccc32)cc1 ; c1ccc(-c2ccc(-c3nc(-c4ccc(-c5nc6ccccc6n5-c5ccccc5)cc4)nc(-c4ccc(-c5nc6ccccc6n5-c5ccccc5)cc4)n3)cc2)cc1 ; c1ccc(-n2c(-c3ccc(-c4nc(-c5ccc(-c6nc7ccccc7n6-c6ccccc6)cc5)nc(-c5cccc6ccccc56)n4)cc3)nc3ccccc32)cc1 ; c1ccc(N(c2ccccc2)c2nc(-c3ccc(-c4nc5ccccc5n4-c4ccccc4)cc3)nc(-c3ccc(-c4nc5ccccc5n4-c4ccccc4)cc3)n2)cc1]

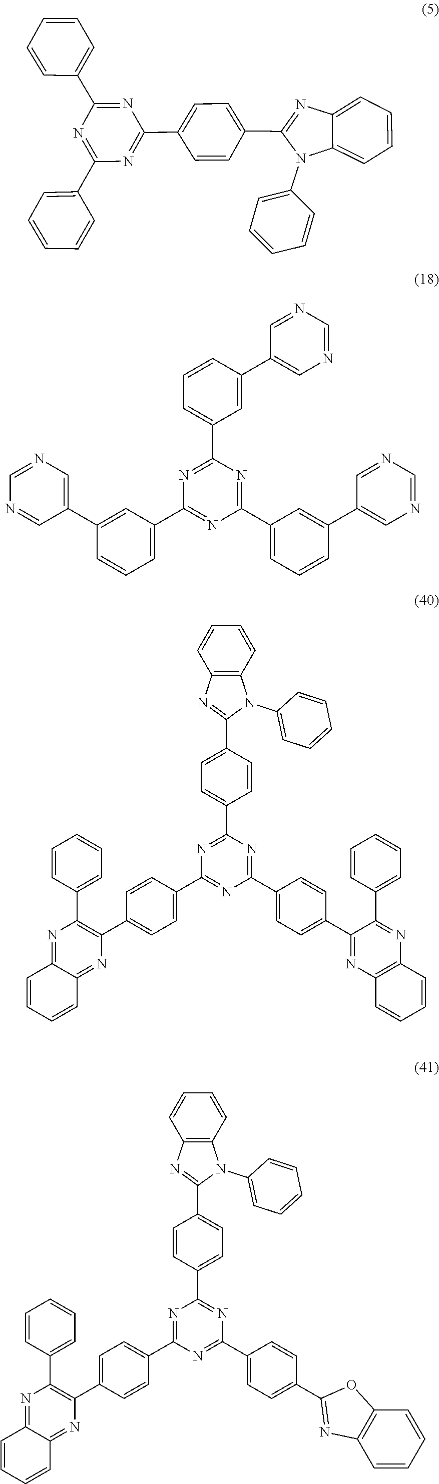 [SMILES: c1ccc(-c2nc(-c3ccccc3)nc(-c3ccc(-c4nc5ccccc5n4-c4ccccc4)cc3)n2)cc1 ; c1cc(-c2cncnc2)cc(-c2nc(-c3cccc(-c4cncnc4)c3)nc(-c3cccc(-c4cncnc4)c3)n2)c1 ; c1ccc(-c2nc3ccccc3nc2-c2ccc(-c3nc(-c4ccc(-c5nc6ccccc6nc5-c5ccccc5)cc4)nc(-c4ccc(-c5nc6ccccc6n5-c5ccccc5)cc4)n3)cc2)cc1 ; c1ccc(-c2nc3ccccc3nc2-c2ccc(-c3nc(-c4ccc(-c5nc6ccccc6o5)cc4)nc(-c4ccc(-c5nc6ccccc6n5-c5ccccc5)cc4)n3)cc2)cc1]

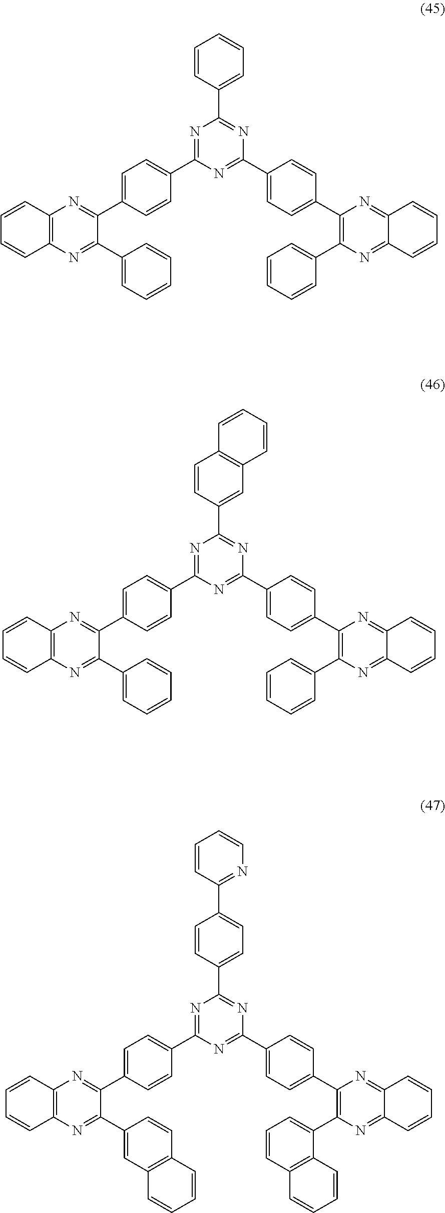 [SMILES: c1ccc(-c2nc(-c3ccc(-c4nc5ccccc5nc4-c4ccccc4)cc3)nc(-c3ccc(-c4nc5ccccc5nc4-c4ccccc4)cc3)n2)cc1 ; c1ccc(-c2nc3ccccc3nc2-c2ccc(-c3nc(-c4ccc(-c5nc6ccccc6nc5-c5ccccc5)cc4)nc(-c4ccc5ccccc5c4)n3)cc2)cc1 ; c1ccc(-c2ccc(-c3nc(-c4ccc(-c5nc6ccccc6nc5-c5ccc6ccccc6c5)cc4)nc(-c4ccc(-c5nc6ccccc6nc5-c5cccc6ccccc56)cc4)n3)cc2)nc1]

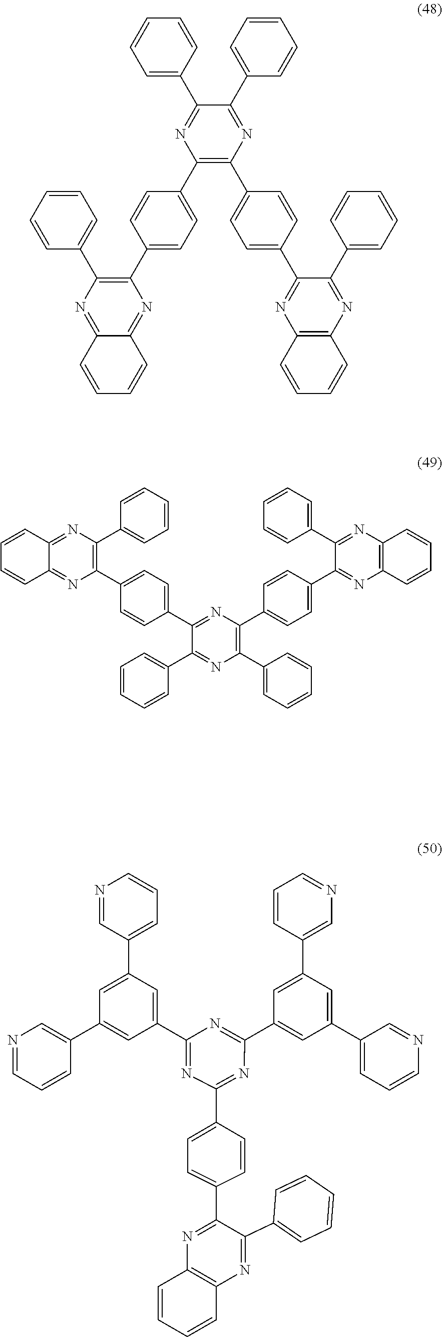 [SMILES: c1ccc(-c2nc(-c3ccc(-c4nc5ccccc5nc4-c4ccccc4)cc3)c(-c3ccc(-c4nc5ccccc5nc4-c4ccccc4)cc3)nc2-c2ccccc2)cc1 ; c1ccc(-c2nc(-c3ccccc3)c(-c3ccc(-c4nc5ccccc5nc4-c4ccccc4)cc3)nc2-c2ccc(-c3nc4ccccc4nc3-c3ccccc3)cc2)cc1 ; c1ccc(-c2nc3ccccc3nc2-c2ccc(-c3nc(-c4cc(-c5cccnc5)cc(-c5cccnc5)c4)nc(-c4cc(-c5cccnc5)cc(-c5cccnc5)c4)n3)cc2)cc1]

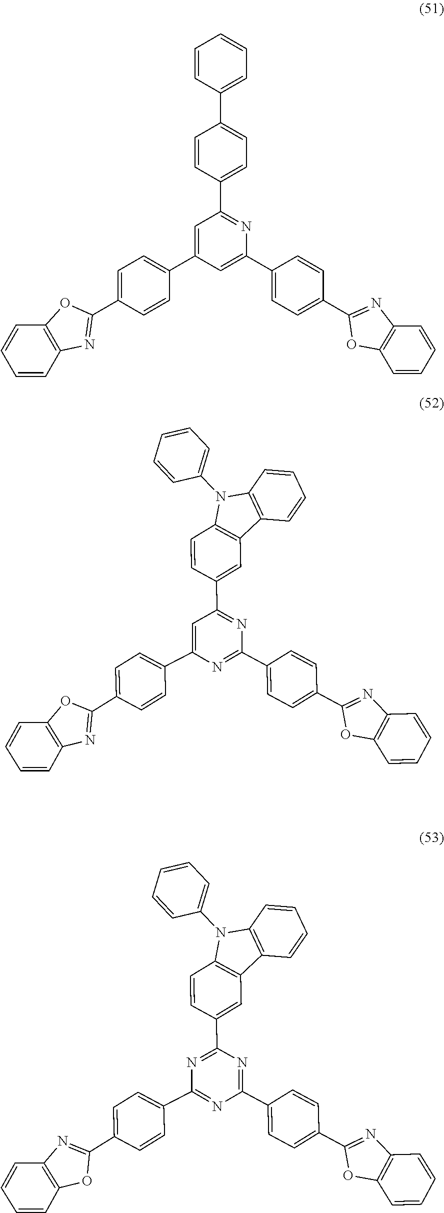 [SMILES: c1ccc(-c2ccc(-c3cc(-c4ccc(-c5nc6ccccc6o5)cc4)cc(-c4ccc(-c5nc6ccccc6o5)cc4)n3)cc2)cc1 ; c1ccc(-n2c3ccccc3c3cc(-c4cc(-c5ccc(-c6nc7ccccc7o6)cc5)nc(-c5ccc(-c6nc7ccccc7o6)cc5)n4)ccc32)cc1 ; c1ccc(-n2c3ccccc3c3cc(-c4nc(-c5ccc(-c6nc7ccccc7o6)cc5)nc(-c5ccc(-c6nc7ccccc7o6)cc5)n4)ccc32)cc1]

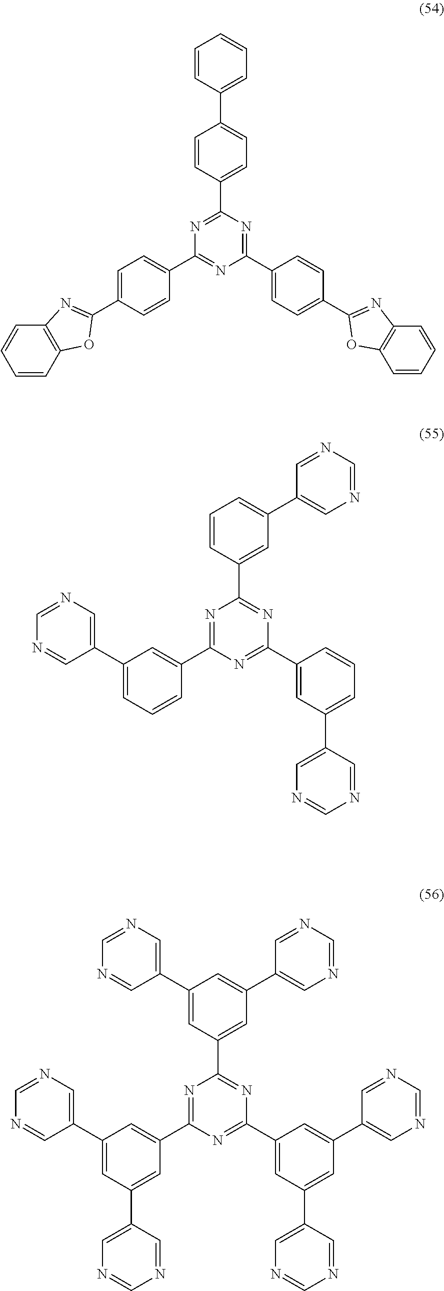 [SMILES: c1ccc(-c2ccc(-c3nc(-c4ccc(-c5nc6ccccc6o5)cc4)nc(-c4ccc(-c5nc6ccccc6o5)cc4)n3)cc2)cc1 ; c1cc(-c2cncnc2)cc(-c2nc(-c3cccc(-c4cncnc4)c3)nc(-c3cccc(-c4cncnc4)c3)n2)c1 ; c1ncc(-c2cc(-c3cncnc3)cc(-c3nc(-c4cc(-c5cncnc5)cc(-c5cncnc5)c4)nc(-c4cc(-c5cncnc5)cc(-c5cncnc5)c4)n3)c2)cn1]

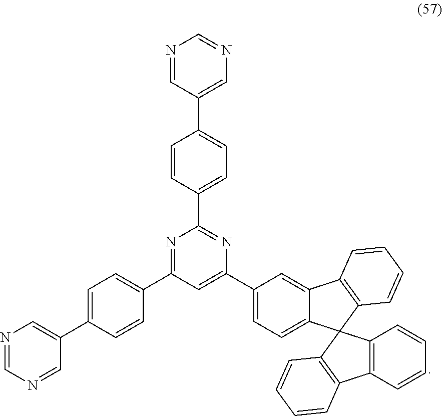 [SMILES: c1ccc2c(c1)-c1ccccc1C21c2ccccc2-c2cc(-c3cc(-c4ccc(-c5cncnc5)cc4)nc(-c4ccc(-c5cncnc5)cc4)n3)ccc21]

The reflective indexes and extinction coefficients of the above 57 compounds and Alq3 compound are measured (test at atmospheric environment) with an ellipsometer (American J. A. Woollam Co. model: ALPHA-SE), and data is as follows:

TABLE 1

| | | | | | Number | |
|---|---|---|---|---|---|---|
| | | | | | of SP2 | |
| | | | | | hybridized | Mole- |
| | n@ | k@ | n@ | n@ | lone pair | cular |
| Compounds | 450 nm | 450 nm | 525 nm | 620 nm | electrons | weight |
| 1 | 2.209 | 0.000 | 2.088 | 2.025 | 5 | 743 |
| 2 | 2.201 | 0.000 | 2.080 | 2.017 | 5 | 769 |
| 3 | 2.170 | 0.000 | 2.053 | 1.992 | 5 | 743 |
| 4 | 2.062 | 0.000 | 1.968 | 1.916 | 5 | 784 |
| 5 | 1.925 | 0.000 | 1.854 | 1.814 | 4 | 501 |
| 6 | 2.043 | 0.080 | 1.900 | 1.844 | 3 | 808 |
| 7 | 1.986 | 0.055 | 1.884 | 1.833 | 3 | 920 |
| 8 | 1.965 | 0.079 | 1.842 | 1.790 | 3 | 1004 |
| 9 | 1.923 | 0.057 | 1.782 | 1.734 | 3 | 1032 |
| 10 | 1.918 | 0.041 | 1.831 | 1.789 | 3 | 920 |
| 11 | 2.026 | 0.047 | 1.904 | 1.850 | 2 | 71 |
| 12 | 1.974 | 0.000 | 1.914 | 1.872 | 2 | 678 |
| 13 | 1.959 | 0.000 | 1.897 | 1.854 | 2 | 629 |
| 14 | 1.938 | 0.015 | 1.862 | 1.822 | 3 | 569 |
| 16 | 1.928 | 0.008 | 1.862 | 1.826 | 2 | 644 |
| 17 | 1.898 | 0.002 | 1.841 | 1.807 | 2 | 678 |
| 18 | 2.204 | 0.000 | 2.119 | 2.063 | 9 | 543 |
| 19 | 2.043 | 0.000 | 1.957 | 1.909 | 3 | 653 |
| 20 | 2.022 | 0.000 | 1.940 | 1.894 | 3 | 639 |
| 21 | 2.028 | 0.004 | 1.956 | 1.914 | 3 | 661 |
| 22 | 1.987 | 0.009 | 1.904 | 1.860 | 4 | 682 |
| 23 | 1.947 | 0.000 | 1.865 | 1.820 | 3 | 591 |
| 24 | 1.920 | 0.000 | 1.854 | 1.818 | 3 | 730 |
| 25 | 1.927 | 0.032 | 1.871 | 1.838 | 3 | 638 |
| 26 | 1.884 | 0.003 | 1.825 | 1.791 | 3 | 574 |
| 27 | 1.885 | 0.000 | 1.832 | 1.799 | 3 | 611 |
| 28 | 1.886 | 0.000 | 1.836 | 1.805 | 3 | 625 |
| 29 | 1.872 | 0.000 | 1.826 | 1.791 | 3 | 547 |
| 30 | 2.024 | 0.000 | 1.937 | 1.887 | 2 | 638 |
| 31 | 1.967 | 0.016 | 1.880 | 1.838 | 2 | 807 |
| 32 | 1.945 | 0.008 | 1.859 | 1.818 | 2 | 731 |
| 33 | 1.924 | 0.010 | 1.862 | 1.825 | 2 | 714 |
| 34 | 2.206 | 0.026 | 1.995 | 1.926 | 4 | 724 |
| 35 | 2.065 | 0.016 | 1.921 | 1.868 | 3 | 591 |
| 36 | 2.039 | 0.000 | 1.942 | 1.893 | 2 | 534 |
| 37 | 1.935 | 0.000 | 1.877 | 1.842 | 2 | 691 |
| 38 | 1.880 | 0.000 | 1.823 | 1.790 | 2 | 601 |
| 39 | 1.871 | 0.003 | 1.810 | 1.777 | 2 | 555 |
| 40 | 2.152 | 0.008 | 2.010 | 1.947 | 8 | 909 |
| 41 | 2.236 | 0.000 | 2.113 | 2.047 | 8 | 822 |
| 42 | 1.960 | 0.099 | 1.897 | 1.822 | 3 | 731 |
| 43 | 1.923 | 0.086 | 1.862 | 1.801 | 3 | 655 |
| 44 | 1.913 | 0.074 | 1.843 | 1.784 | 3 | 745 |
| 45 | 2.187 | 0.000 | 2.078 | 2.016 | 7 | 717 |
| 46 | 2.178 | 0.013 | 2.057 | 1.992 | 7 | 767 |
| 47 | 2.209 | 0.000 | 2.088 | 2.025 | 8 | 894 |
| 48 | 2.062 | 0.000 | 1.968 | 1.916 | 6 | 792 |
| 49 | 2.201 | 0.000 | 2.080 | 2.017 | 6 | 792 |
| 50 | 2.170 | 0.000 | 2.053 | 1.992 | 9 | 821 |
| 51 | 2.257 | 0.000 | 2.119 | 2.050 | 5 | 617 |
| 52 | 2.204 | 0.000 | 1.937 | 1.887 | 6 | 707 |
| 53 | 2.093 | 0.000 | 2.009 | 1.957 | 7 | 708 |
| 54 | 2.099 | 0.000 | 1.988 | 1.930 | 7 | 619 |
| 55 | 2.077 | 0.000 | 2.012 | 1.970 | 9 | 543 |
| 56 | 2.494 | 0.077 | 2.110 | 2.019 | 15 | 777 |
| 57 | 2.039 | 0.000 | 1.942 | 1.893 | 7 | 703 |
| Alq3 | 1.780 | 0.017 | 1.733 | 1.702 | 3 | 459 |
| (control) | | | | | | |

wherein n is the reflective index, and k is the extinction coefficient.

It can be seen from the data in the above table that the above compounds listed in the disclosure contain the number of SP2 hybridized lone pair electrons being ≥2, have the reflective indexes of 1.8 or more in the field of blue light, preferably 1.8-2.3, the reflective indexes of 1.8 or more in the field of green light, preferably 1.8-2.2, and the reflective indexes of 1.7 or more in the field of red light, preferably 1.7-2.1; and the extinction coefficients of all the above materials in the field of visible light are 0.1 or less.

In the second aspect:

The disclosure also provides a structure and preparation method of an organic electroluminescent device containing a capping layer. Next, the disclosure will be described in detail in combination with drawings and embodiments. However, they can be implemented in different forms, and should not be explained as being limited to embodiments described herein. On the contrary, these embodiments are provided so that the disclosure is more complete and thorough.

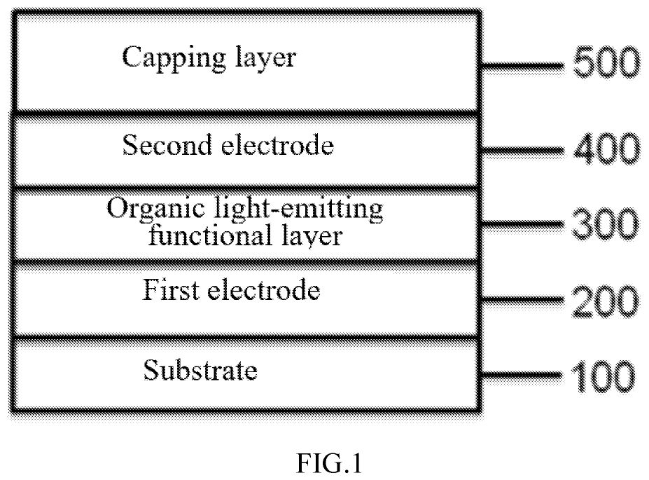

FIG. 1 is a diagram of a cross-sectional structure of an organic electroluminescent device containing a capping layer provided by the disclosure. As shown in FIG. 1, an organic electroluminescent device comprises a substrate layer 100, as well as a first electrode layer 200, an organic light-emitting functional layer 300, a second electrode layer 400 and a capping layer 500 which are successively formed on the substrate layer 100.

The substrate layer 100 can select any substrates used in the typical organic light-emitting device. It can be a glass or transparent plastic substrate, or an opaque material such as a silicon or stainless steel substrate, or a flexible PI film. Different substrates have different mechanical strength, thermal stability, transparency, surface flatness and waterproofness. Use methods are different based on different properties of substrates.

The first electrode layer 200 is formed on the substrate layer 100, the first electrode layer 200 can be a cathode or anode. Here, the first electrode layer 200 can be a reflecting electrode such as silver (Ag), magnesium (Mg), aluminum (Al), Au, nickel (Ni), chromium (Cr), ytterbium (Yb) or reflecting films formed by alloys thereof; and has high work content and a transparent or semi-transparent electrode layer formed on the reflecting film.

The transparent or semi-transparent electrode layer can be formed by indium tin oxide (ITO), indium zinc oxide (IZO), zinc oxide (ZnO), aluminum zinc oxide (AZO), indium gallium oxide (IGO), indium oxide (In₂O₃) or stannic oxide (SnO₂).

The above first electrode layer 200 can be formed through sputtering, ion plating, vacuum evaporation, spin coating, electronic beam evaporation or chemical vapor deposition (CVD) and the like, preferably through sputtering.

The thickness of the first electrode layer 200 depends on used materials, generally ranges from 5 nm or more to 1 μm or less, preferably from 10 nm or more to 1 μm or less, more preferably from 10 nm or more to 500 nm or less, particularly preferably from 10 nm or more to 300 nm or less, most preferably from 10 nm or more to 200 nm or less. The resistance of the transparent electrode material sheet is preferably set below hundreds of ohms/sheet, and more preferably set above 5 ohm/sheet and below 50 ohm/sheet. The surface (the surface connected with the organic layer) of the first electrode layer 200 can be subjected to UV-ozone cleaning, oxygen-enriched plasma cleaning and argon plasma cleaning. In order to inhibit the short circuit and defects of the OLED device, the surface roughness can be preferably controlled below 20 nm through particle size miniaturization and grinding after film formation.

When the first electrode layer 200 has high resistance, an auxiliary electrode can be set to reduce the resistance. The auxiliary electrode can be an electrode obtained by juxtaposing silver, copper, chromium, aluminum, titanium, aluminum alloy, silver alloy and other metals or laminations thereof inside the transparent electrode.

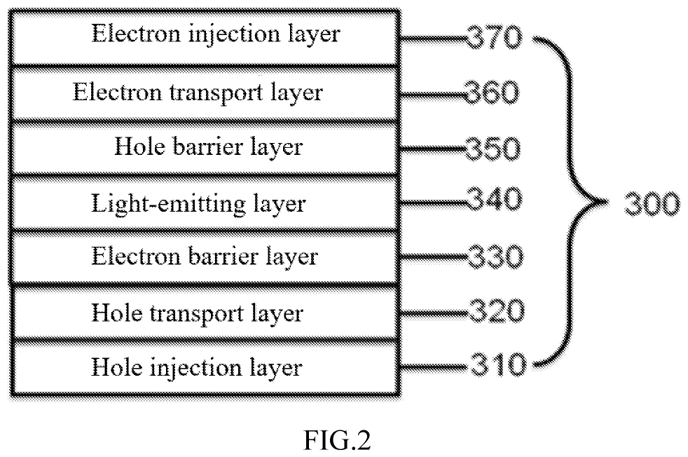

FIG. 2 is a diagram of a cross-sectional structure of an organic light-emitting functional layer in the organic electroluminescent device provided by the disclosure.

As shown in FIG. 2, the organic light-emitting functional layer 300 can include a light-emitting layer 340 (EML), and a hole transport region can be formed between EML and the first electrode layer 200, and an electron transport region can be formed between EML and the second electrode layer 400. The hole transport region can include at least one of a hole injection layer 310 (HIL), a hole transport layer 320 (HTL) and an electron barrier layer 330 (FBL). The electron transport region can include at least one of a hole barrier layer 350 (HBL), an electron transport layer 360 (ETL) and an electron injection layer 370 (EIL). Thus, the organic light-emitting functional layer 300 includes a combination of at least two of the hole injection layer, the hole transport layer, the electron barrier layer, the hole barrier layer, the electron transport layer and the electron injection layer.

The thickness of the organic light-emitting functional layer 300 is 50 nm-1000 nm.

As the hole injection layer material, the hole transport layer material and the electron barrier layer material (HIL310, HTL320 and EBL330), any material can be selected from relevant materials used for the OLED device to be used.

Examples of the above materials can be styrene compounds such as phthalocyanine derivatives, triazole derivatives, triarylmethane derivatives, triarylamine derivatives, oxazole derivatives, oxadiazole derivatives, hydrazone derivatives, stilbene derivatives, pyridyline derivatives, polysilane derivatives, imidazole derivatives, phenylenediamine derivatives, amino-substituted quilone derivatives, styrylanthracene derivatives and styrylamine derivatives, conductive polymer oligomers such as fluorene derivatives, spirofluorene derivatives, silazane derivatives, phenylamine copolymers, porphyrin compounds, carbazole derivatives, polyarylalkane derivatives, polyphenylene ethylene and derivatives thereof, polythiophene and derivatives thereof, poly-N-vinyl carbazole derivatives and thiophene oligomers, aromatic tertiary amine compounds, styrylamine compounds, triamines, tetramine, benzidines, propanediamine derivatives, p-phenylenediamine derivatives, m-phenylenediamine derivatives, 1,1′-bis(4-diaryaminophenyl) cyclohexane, 4,4′-bis(diarylamines) biphenyls, bis [4-(diarylamino) phenyl] methanes, 4,4′-bis (diarylamino) terphenyls, 4,4′″-bis(diarylamino) tetrabiphenyls, 4,4′-bis (diarylamino) diphenyl ethers, 4,4′-bis(diarylamino) diphenylthioalkanes, bis [4-(diarylamino) phenyl] dimethylmethanes, bis[4-(diarylamino) phenyl]-bis(trifluoromethyl) methanes or 2,2-diphenylethylene compounds, or the like.

As triarylamine derivatives, examples are diploids, triploids, tetraploids and pentaploids of triphenylamine, 4,4′-bis [N-phenyl-N-(4″-methylphenyl) amino] biphenyl, 4,4′-bis [N-phenyl-N-(3″-methylphenyl) amino] biphenyl, 4,4′-bis [N-phenyl-N-(3″-methoxyphenyl) amino] biphenyl, N, N′-diphenyl-N, N′-bis (1-naphthyl) (1,1′-biphenyl)-4,4′-diamine (NPB), 4,4′-bis [N-[4′-[N″-(1-naphthyl)-N″-phenylamino] biphenyl]-N-phenylamino] biphenyl (NTPA), 3,3′-dimethyl-4,4′-bis [N-phenyl-N-(3″-methylphenyl) amino] biphenyl, 1,1-bis[4′-[N, N-bis(4″-methylphenyl) amino] phenyl] cyclohexane, 9,10-bis[N-(4′-methylphenyl)-N-(4″-n-butylphenyl) amino] phenanthrene, 3,8-bis(N,N-diphenylamino)-6-phenylphenanthridine, 4-methyl-N,N-bis[4″, 4′″-bis [N′,N″-bis (4-methylphenyl) amino] biphenyl-4-yl] phenylamine, N,N′-bis [4-(diphenylamino) phenyl]-N, N′-diphenyl-1,3-diaminobenzene, 1,3,5-tris (triphenylamino) benzene, 4,4′,4″-tris (N-carbazole) triphenylamine, 4,4′,4″-tris [N-3′″-methylphenyl)-N-phenylamino] triphenylamine, 4,4′,4″-tris[N,N-bis (4′″-tert-butylphenyl-4″″-yl) amino] triphenylamine or 1,3,5-tris [N-(4′-diphenylaminophenyl)-N-phenyl amino] benzene and the like.

As porphyrin compounds, porphyrin, 1,10,15,20-tetraphenyl-21H, 23H-porphyrinone (II), 1,10,15,20-tetraphenyl-21H,23H-porphyrin zinc (II) or 5,10,15,20-tetra(pentafluorophenyl)-21H,23H porphyrin is taken as an example; as a phthalocyanine derivative, silicon phthalocyanine oxide, aluminum oxide phthalocyanine, nonmetal phthalocyanine, dilithium phthalocyanine, copper tetramethylphthalocyanine, copper phthalocyanine, chromium phthalocyanine, zinc phthalocyanine, aluminum phthalocyanine, titanium oxide phthalocyanine, magnesium phthalocyanine or copper octamethylphthalocyanine or the like is taken as an example.

As aromatic tertiary amine compounds and styrylamine compounds, N,N,N′,N′-tetraphenyl-4,4′-diaminobenzene, N,N′-diphenyl-N,N′-bis-(3-methylphenyl)-[1,1′-biphenyl]-4,4′-diamine, 2,2-bis (4-di-p-triaminophenyl) propane, 1,1-bis(4-di-p-triaminophenyl) cyclohexane, N,N,N′,N′-tetra-p-methylphenyl-4-4′-diaminobenzene, 1,1-bis(4-di-p-triaminophenyl)-4-phenyl-cyclohexane, bis(4-dimethylamino-2-methylphenyl) phenylmethane, bis(4-di-p-tolylaminophenyl) phenylmethane, N,N′-diphenyl-N,N′-bis (4-methoxyphenyl)-4,4′-diaminobiphenyl, N,N,N′,N′-tetraphenyl-4,4′-diaminophenyl ether, 4,4′-bis (diphenylamino) tetrabenzene, N,N,N-tris(p-tolylamino) amine, 4-(di-p-tolylamino)-4′-[4(di-p-tolylamino)styryl] phenylenediethylene, 4-N,N-diphenylamino-2-diphenylvinyl benzene, 3-methoxy-4′-N,N-diphenylamino-phenylenediethylene or N-phenylcarbazole or the like.

Where, aryl-bis(4-diarylaminophenyl) amines, p-phenylenediamine derivatives, 4,4′-diaminobiphenyl derivatives, 4,4′-diaminodiphenylthiane derivatives, 4,4′-diaminodiphenylmethane derivatives, 4,4′-diaminodiphenylether derivatives, 4,4′-diaminodiphenylmethane derivatives, 4,4′-diaminodiphenylether derivatives, 4,4′-diaminotetraphenylmethane derivatives, 4,4′-diaminohomophenylethylene derivatives, 1,1-diarylhexanes, 4,4″-diaminopolyphenyl derivatives, 5,10-bis-(4-aminophenyl) anthracene derivatives, 2,5-diarylpyridine, 2,5-diarylfurans, 2,5-diarylthiophenes, 2,5-diarylpyrroles, 2,5-diaryl-1,3,4-oxadiazoles, 4-(diarylamino) phenylenediethylenes, 4,4′-bis(diarylamino) phenylenediethylenes-N,N-diaryl-4-(2,2-diphenylvinyl) phenylamines, 2,5-diaryl-1,3,4-triazoles, 1,4-bis (4-aminophenyl) naphthalene derivatives, 2,8-bis (diarylamino)-5-thiatons or 1,3-bis (diarylamino) isoindoles or the like, more preferably tris[4-[N-(3-methylphenyl)-N-phenylamino] phenyl] amines, N-([1,1′-biphenyl]-2-yl)-N-(9,9-dimethyl-9H-furan-2-yl)-9,9′-spirodifluorene-2-amines or tris[4-[N-(2-naphthyl)N-phenylamino] phenyl] amines or the like.

At least one of HIL310 and HTL320 can also include a charge generation material used for improving conductivity. The charge generation material can be a p-dopant. Non-limiting compounds of the p-dopant include quinone derivatives, such as tetracyanquinone dimethane (TCNQ) and 2,3,5,6-tetrafloro-tetracyan-1,4-benzoquinone dimethane (F4-TCNQ); or hexaazatriphenylene derivatives, such as 2,3,6,7,10,11-hexacyano-1,4,5,8,9,12-hexaazatriphenylene (HAT-CN); or cyclopropane derivatives, such as 4,4′,4″-((1E,1′E,1″E)-cyclopropane-1,2,3-trimethylene tris(cyanoformyl)) tris(2,3,5,6-tetrafluorobenzyl); or metal oxides, such as tungsten oxide and molybdenum oxide, but not limited thereto.

It is required that the triplet (T1) energy level of the material in EBL330 is higher than the T1 energy level of a host material in the light emitting layer 340, which can play a role in blocking the energy loss of the light-emitting layer; the HOMO energy level of the EBL330 material is between the HOMO energy level of the HTL320 material and the HOMO energy level of the host material of the light-emitting layer 340, which is beneficial to injection of the hole into the light-emitting layer from the positive electrode, and meanwhile it is required that the EBL330 material has high hole mobility, which is beneficial to hole transport and reduction in device application power; the LUMO energy level of the EBL330 material is higher than the LUMO energy level of the host material of the light-emitting layer 340, which can play a role in blocking electrons, that is to say, the EBL330 material is required to has wide energy gap (Eg). THE EBL330 materials meeting the above conditions can be triarylamine derivatives, fluorine derivatives, spiroflurorene derivatives, dibenzofuran derivatives, carbazole derivatives and the like. Among them, the triarylamine derivatives are preferred, such as N⁴, N⁴-bis ([1,1′-biphenyl]-4-yl)-N^{4′}-phenyl N^{4′}-[1,1′:4′,1′-terphenyl]-4-yl-[1,1′-biphenyl]-4,4′-diamine; spirofluorene derivatives, such as N-([1,1′-diphenyl]-4-yl)-N-(9,9-dimethyl-9H-furan-2-yl)-9,9′-spirofluorene-2-amine; dibenzofuran derivatives, such as N,N-bis ([1,1′-biphenyl]-4-yl)-3′-(dibenzo[b,d]furan-4-yl)-[1,1′-biphenyl]-4-amine, but not limited thereto.

In order to obtain a high-efficiency OLED device, the light-emitting layer 340 can adopt the same doping material or multiple doping materials. The doping material can be a pure fluorescent material, a delayed fluorescence (TADF) material or a phosphorescent material, or is formed by matching and combining different fluorescent materials, TADF materials and phosphorescent materials. The light-emitting layer 340 can be a single light-emitting layer material, or a horizontally or vertically stacked composite light-emitting layer material. Multiple structures for the light-emitting layer 340 constituting the OLED illuminant are listed as follows:

(1) a single organic light-emitting layer material;

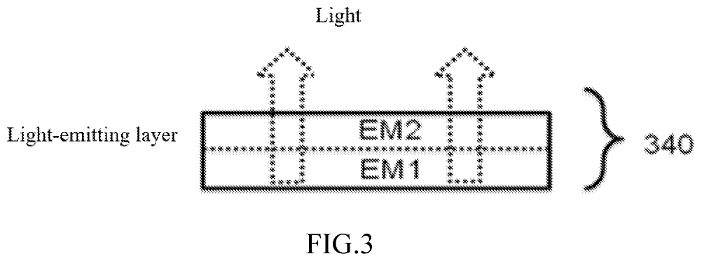

(2) any combination of a blue organic light-emitting layer material and a green, yellow or red light-emitting layer material, regardless of sequence, as shown in FIG. 3;

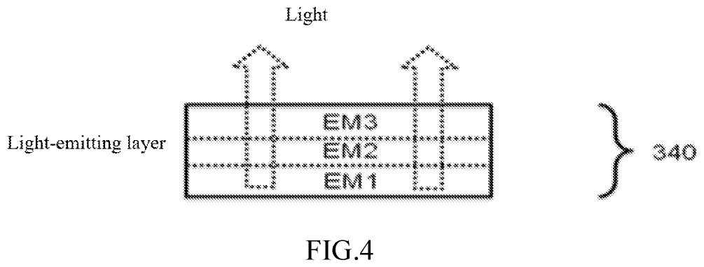

(3) a combination of any two of the blue organic light-emitting layer material and the green, yellow or red light-emitting layer material, regardless of sequence, as shown in FIG. 4;

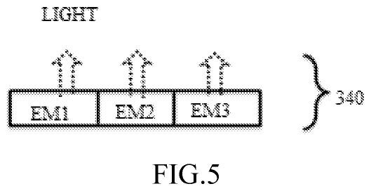

(4) horizontal arrangement of the blue organic light-emitting layer material, the green organic light-emitting layer material and the red organic light-emitting layer material, as shown in FIG. 5;

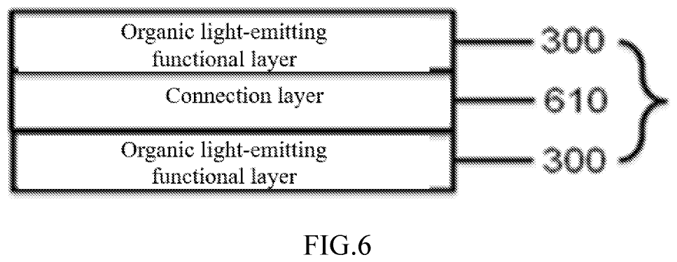

(5) any combination of the blue organic light-emitting layer material and the green, yellow or red light-emitting layer material, and charge transport is conducted through a connection layer to form a device structure having two laminated layers, as shown in FIG. 6;

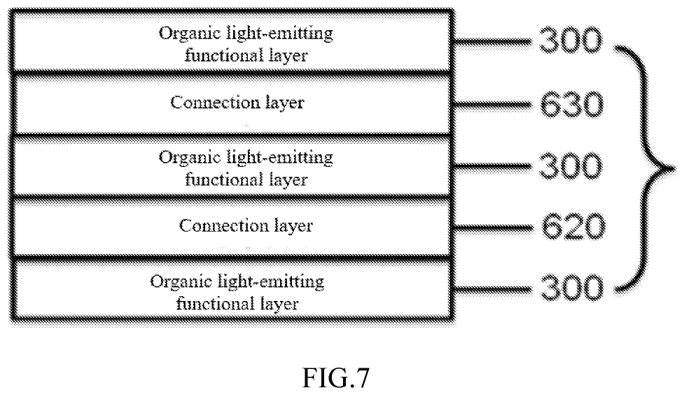

(6) a combination of any two of the blue organic light-emitting layer material and green, yellow or red light-emitting layer material, and charge transport is conducted through the connecting layer to form a device structure having three laminated layers, as shown in FIG. 7.

Preferably, the organic light-emitting functional layer includes the light-emitting layer, and the light-emitting layer includes one or a combination of at least two of a blue light-emitting pixel, a green light-emitting pixel, a red light-emitting pixel and a yellow light-emitting pixel.

In order to adjust the effective combination of carrier charges in the light-emitting layer, the film thickness of the light-emitting layer 340 constituting the OLED illuminant can be adjusted arbitrarily as required, or the light-emitting layers that cannot be colored can be alternately superposed and combined as required, or charge barrier layers having different functional uses and the like are added in the organic layer adjacent to the light-emitting layer.

As the host material of the light-emitting layer substance constituting the above OLED illuminant, it needs to not only have bipolar charge transport characteristics but also have appropriate energy level, can effectively transfer excitation energy generated due to recombination of electrons and holes to a guest light-emitting material, namely the doping material. Such the materials include for example distyrylarylene derivatives, stilbene derivatives, carbazole derivatives, triarylamine derivatives, anthracene derivatives, pyrene derivatives, triazine derivatives, xanthone derivatives, triphenylene derivatives, azabenzene derivatives, hexabenzobenzene derivatives or bis(2-methyl-8-quinoline) (p-phenylphenol) aluminum (BAlq).

As the guest material that can produce blue fluorescence, blue phosphorescence, green fluorescence, green phosphorescence and blue-green fluorescence, it not only needs to have an extremely high fluorescence quantum light-emitting efficiency, but also needs to have a proper energy level and can effectively absorb the excitation energy of the host material to emit light, and such the material is not specifically limited. It includes for example distyrylamine derivatives, pyrene derivatives, anthracene derivatives, triazine derivatives, xanthone oxaanthrone derivatives, benzoxazole derivatives, benzothiazole derivatives, benzimidazole derivatives, chrysene derivatives, azaphenanthrene derivatives, stilbene benzene derivatives or tetraphenylbutadiene derivatives. Among them, 4,4′-bis[2-(9-ethylcarbazole-2-yl)-vinyl] biphenyl (BCzVBi), perylene and the like can be used. A single or a combination of more than two of quaterphenyl compounds, biphenyl compounds, benzimidazole compounds, benzoxazole compounds, benzoxadiazole compounds, styrylbenzene compounds, biphenylpyrazine compounds, butadiene compounds, naphthalene dicarboximide compounds, purple perilla compounds, aldehyde azine compounds, cyclopentadiene compounds, pyrrolopyrroleformyl compounds, styrylamine compounds, coumarin compounds, aromatic xylene theophylline compounds, metal complexes with 8-quinolinol substances as ligands or polyphenyl compounds or the like are also listed. Among these compound materials, the specific implementing materials that can be listed in the disclosure include aromatic xylene theophylline compounds, such as 4,4′-bis(2,2-di-1-butylphenylvinyl) diphenyl (DTBPBBi for short) or 4,4′-bis(2,2-diphenylvinyl) diphenyl (DPVBi for short) and derivatives thereof.

Relative to the fluorescent host material, the content (doping amount) of the fluorescent guest material is preferably 0.01% by weight or more and 20% by weight or less, more preferably 0.1% by weight and 10% by weight. As the fluorescent guest material, when the blue fluorescent guest material is used, relative to the fluorescent host material, the content of the blue fluorescent guest material is preferably 0.1% by weight or more and 20% by weight or less. As long as within this range, the effective energy distribution equilibrium is generated between the high-energy blue illuminant and the low-energy red illuminant, and expected electroluminescence with blue and red light-emitting phase equilibrium intensity can be obtained.

The light-emitting layer 340 included in the above OLED device can not only use the above fluorescent light-emitting material, but also use the phosphorescent material. Compared with the fluorescent materials, the phosphorescent materials can simultaneously utilize singlet and triplet excitons in the process of emitting light. Theoretically, the internal quantum efficiency can reach 100%, thereby greatly improving the light-emitting efficiency of the light-emitting device.

As the blue phosphorescent doping material, there is no special limitation as long as it is a substance having a blue phosphorescent light-emitting function. For example, metal complexes of iridium, titanium, platinum, rhenium, palladium and the like can be listed. Among them, at least one complex, having a phenyl pyridine skeleton, a dipyridine skeleton, a porphyrin skeleton and the like, in the ligands of the above metal complexes is preferred. More specifically, bis[4,6-difluorophenylpyridine-N,C2′]-methylpyridineiridium, tris[2-(2,4-difluorophenyl) pyridine-N,C2′] iridium, bis[2-(3,5-trifluoromethyl) pyridine-N,C2′]-methylpyridineiridium or bis[4,6-difluorophenylpyridine-N,C2′] acetylacetoiridium can be listed.

As the green phosphorescent doping material, there is no special limitation as long as it is a substance having a green phosphorescent light-emitting function. For example, the metal complexes of iridium, pegs, platinum, rhenium, palladium and the like can be listed, and at least one complex, having a phenyl pyridine skeleton, a dipyridine skeleton, a porphyrin skeleton and the like, in the ligands of the above metal complexes can also be listed as the green phosphorescent dopant. More particularly, (face)-tris(2-phenylpyridine) iridium (Ir(ppy)₃), bis[2-phenylpyridine-N,C2′]-acetylacetone iridium or (face)-tri (5-fluoro-2-(5-trifluoromethyl-2-pyridyl) phenyl-C, N] iridium and the like can be listed.

As the red phosphorescent doping materials, octaethyl porphyrin platinum (II) (PtOEP), tri(2-phenylisoquinoline)iridium (Ir(piq)₃), bis(2-(2′-benzothiophenyl)-pyridine-N,C3′) iridium (acetylacetone compound) (Btp₂Ir(acac)) and the like can be exemplified.

Calculated relative to the phosphorescent host material, the content (doping amount) of the phosphorescent doping material is preferably 0.01% by weight or more and 30% by weight or less, more preferably 0.1% by weight or more and 20% by weight or less. When the green phosphorescent doping material is used, calculated relative to the phosphorescent host material, the content of 0.1% by weight or more and 20% by weight or less is preferred.

In addition, as the phosphorescent host material, there is no specific limitation as long as its triple energy is greater than that of the phosphorescent dopant. For example, carbazole derivatives, naphthisodiazine derivatives, triazine derivatives, triazole derivatives and hydroxyquinoline metal complexes can be listed. Specifically, 4,4′,4′-tri(9-carbazolyl) triphenylamine, 4,4′-bis(9-carbazolyl)-2,2′-dimethyl biphenyl, 2,9-dimethyl-4,7-diphenyl-1,10-o-diazaphenyl (BCP), 3-phenyl-4-(1′-naphthyl)-5-phenylcarbazole, tris(8-hydroxyquinoline) aluminum (Alq) or bis-(2-methyl-8-hydroxyquinoline-4-(phenylphenol) aluminum can be listed.

In addition to the fluorescent or phosphorescent host and guest materials used in the light-emitting layer, the light-emitting layer material can also adopt non host/guest doping system materials, such as exciplex energy transfer and interface luminescence; the light-emitting layer material can also adopt host/guest materials having a thermal activation delayed fluorescence (TADF) function, and forms of mutual combination of TADF functional materials and the above fluorescent and phosphorescent materials.

The materials constituting the hole barrier layer 350 and the electron transport layer 360 of the above OLED device can be arbitrarily selected from the materials for OLED having electron transport characteristics for use. Such the materials can be listed, including oxadiazole derivatives such as 1,3-bis[5′-(p-tert-butylphenyl)-1,3,4-oxadiazole-2′-yl] benzene, 2-(4-biphenyl)-5-(4-tert-butylphenyl)-1,3,4-oxadiazole derivatives, triazole derivatives such as 3-(4-tert-butylphenyl)-4-phenyl-5-(4-biphenyl)-1,2,4-triazole, triazine derivatives, quinoline derivatives, quinoxaline derivatives, dibenzoquinone derivatives, nitro-substituted dione derivatives, thiapyran dioxide derivatives, anthraquinone dimethane derivatives, thiapyran dioxide derivatives, heterocyclic tetraanhydrides such as naphthylperylene, carbodiimide, dione derivatives, anthraquinone dimethane derivatives, anthrone derivatives, stilbene pyrazine derivatives, silicon heterocyclopentadiene derivatives, phenanthroline derivatives or imidazopyridine derivatives.

In addition, organic metal complexes such as bis(10-benzo [h] hydroxyquinoline) beryllium, beryllium salt of 5-hydroxybrass, aluminum salt of 5-hydroxybrass, or metal complexes of 8-hydroxyquinoline or its derivatives, such as tri(8-hydroxyquinoline) aluminum (Alq), tris(5,7-dichloro-8-hydroxyquinoline) aluminum, bis(2-methyl-8-hydroxyquinoline) (p-phenylphenol) aluminum (BAlq), tris(5,7-dibromo-8-hydroxyquinoline) aluminum. Metal chelating agent compounds containing chelating agents, for example plant hormones (generally, 8-hydroxyquinoline) such as tris(2-methyl-8-hydroxyquinoline) aluminum, and hydroxyquinoline metal complexes can also be listed. In addition, examples of the central metals of these metal complexes being replaced by the metal complexes of beryllium, indium, magnesium, copper, calcium, tin, zinc or aluminum can also be listed. Materials where non-metal and metal phthalocyanine or their ends are replaced as alkyl, sulfo and the like are preferably used. Among them, 2,9-dimethyl-4,7-diphenyl-1,10-orthophenanthrolene (BCP), 3-phenyl-4-(1′-naphthalene)-5-phenyl-1,2,4-triazole (TAZ) are more preferably used.

It is required that the triplet (T1) energy level of the material in HBL350 is higher than the T1 energy level of the host material in the light-emitting layer 340, which can play a role in blocking the energy loss of the light-emitting layer material; the HUMO energy level of the EBL350 material is lower than the HUMO energy level of the host material in the light-emitting layer 340, which plays a role in blocking holes. At the same time, the HBL350 material is required to have a high electron mobility, which is conducive to electron transport and reduction in the application power of the device; the HBL350 material meeting the above conditions can be triazine derivatives, azabenzene derivatives and the like, wherein it preferably selects triazine derivatives, but is not limited thereto.

EIL370 can be formed by one or more of the following substances: alkali metals; alkali earth metals; halides of alkali metals and alkali earth metals; oxides of alkali metals and alkali earth metals, carbonates of alkali metals and alkali earth metals; oxalates of alkali metals and alkali earth metals or fluoroaluminates of alkali metals and alkali earth metals. Li, Ca, Sr, LiF, CsF, BaO, Li₂CO₃, CaCO₃, Li₂C₂O₄, Cs₂C₂O₄ and CsAlF₄ can be exemplified. In some embodiments, EIL370 can include at least one metal, such as one or more of Yb, Sc, V, Y, In, Ce, Sm, Eu or Tb.

A second electrode layer 400 is formed on the organic light-emitting functional layer 300. The second electrode layer can be a cathode or an anode, and can be a transparent electrode or a semi-translucent electrode. The second electrode layer 400 can be made of lithium, calcium, lithium fluoride/calcium, lithium fluoride/aluminum, aluminum, silver, magnesium or alloys thereof to form a thin film having a low work function. Further, the second electrode layer 400 can be made of an alloy including silver and at least one metal, the at least one metal including aluminum, platinum, ytterbium, chromium or magnesium. Moreover, the weight ratio of Ag in the alloy can be the same as those of other metals or greater or less than those of other metals. For example, the second electrode layer 400 can be formed from an Ag—Mg alloy, wherein the mass ratio of Ag to Mg can be 90:10˜10:90. Alternatively, the second electrode layer 400 can be formed of an alloy including at least one metal such as silver, gold, platinum, copper, nickel or tungsten and at least one metal such as ytterbium, indium, magnesium or chromium. These metal films can form transparent or semi-translucent electrodes by adjusting the thicknesses of the films. Therefore, light generated by the organic light-emitting functional layer 300 can be emitted through the second electrode layer 400. Moreover, the thickness of the second electrode layer 400 can be 5-30 nm.

A capping layer 500 is formed on the second electrode layer 400, and the capping layer 500 can be an organic material, an inorganic material or a combination thereof. In particular, the material used in the capping layer 500 is the organic compound material described in the first aspect of the disclosure.

Hereinafter, the disclosure will be further described according to embodiments in combination with FIG. 1 and FIG. 2.

The Preparation of the Organic Electroluminescent Device of the Disclosure

The thickness of each layer of material for the preparation of the organic electroluminescent device of the disclosure or each layer of organic electroluminescent device of the disclosure can refer to the above description.

Referring to FIG. 1, the organic electroluminescent device of the disclosure includes a the substrate layer 100, the first electrode layer 200, the organic light-emitting functional layer 300, the second electrode layer 400 and the capping layer 500.

On the substrate layer, a well-known method can be used to form a barrier layer (which can be composed of inorganic materials or/and organic materials and used for preventing foreign matters from penetrating to the substrate and the device) and a wiring layer (which can include drive TFT, a capacitor, a wire and a low-temperature polysilicon LTPS).

In one embodiment, the first electrode layer 200 can be a reflecting electrode and the second electrode layer 400 can be a transparent or semi-translucent electrode. Therefore, light generated by the organic light-emitting functional layer 300 can be emitted directly by the second electrode layer 400, or can be reflected by the first electrode layer 200 to the second electrode layer 400 to be emitted. The first electrode layer 200 can be prepared by for example evaporation or sputtering. The second electrode layer 400 can be prepared by for example vacuum evaporation.

The organic light-emitting functional layer 300 can include a light-emitting layer 340 (EML), and a hole transport region can be formed between EML and the first electrode layer 200, and an electron transport region can be formed between EML and the second electrode layer 400. The hole transport region can include at least one of the hole injection layer 310 (HIL), the hole transport layer 320 (HTL) and the electron barrier layer 330 (EBL). The electron transport region can include at least one of the hole barrier layer 350 (HBL), the electron transport layer 360 (ETL) and the electron injection layer 370 (EIL).

The organic light-emitting functional layer 300 can be composed of small-molecular organic materials or polymer materials, and the organic light-emitting functional layer 300 can be prepared through multiple methods such as vacuum evaporation, solution spin coating, silk-screen printing and ink-jet printing.

The capping layer 500 can be composed of inorganic materials, organic small-molecular materials and polymer materials, particularly, the capping layer 500 is composed of the organic compound materials described in the first aspect of the disclosure, and the capping layer 500 can be prepared by using multiple methods such as vacuum evaporation, solution spin coating, silk-screen printing and ink-jet printing.

In addition, a panchromatic organic electroluminescent device including the structure of FIG. 3, FIG. 4, FIG. 5, FIG. 6 or FIG. 7 can be prepared with reference to the structure of the organic electroluminescent device of FIG. 1 and FIG. 2. That is to say, the organic light-emitting device according to these embodiments can be configured into multiple structures, for example a monochromatic light-emitting device and a polychromatic light or white light organic electroluminescent device.

The organic electroluminescent device containing the capping layer prepared by the compound of the disclosure can be used in the field of OLED illumination and display, particularly, can be used in the field of commercial industry, for example, display screens of products and devices such as POS machines and ATM machines, copiers, vending machines, game machines, public telephone booths, gas stations, punch card machines, access control systems, electronic scales; in the field of communication, for example, display screens of products such as 3G mobile phones, various visual intercom systems (videophones), mobile network terminals and ebook (electronic-book)); in the field of computers, for example, display screens of computer fields, such as home and commercial computers (PC/workstation and the like), PDA and notebook computers; in the field of consumer electronic products, for example, display screens of products such as decorative products (soft screens) and lamps, various audio equipment, MP3, calculators, digital cameras, head mounted displays, digital cameras, portable DVD, portable televisions, electronic clocks and watches, hand-held game consoles and various household appliances (OLED TVS); in the field of transportation, for example, various indicative landmark display screens such as GPS, car audios, car phones, aircraft instruments and equipment. For example, a microdisplay, this technology was first used for fighter pilots, and the current wearable computers can also use the technology, mobile devices are not limited by large display volume and much electricity consumption if the technology is used. Preferably, the organic electroluminescent device containing the capping layer prepared by the compound of the disclosure can be used in the field of illumination and display, preferably in the fields of smart phones, tablet computers, intelligent wearable devices, large-scale applications such as television, VR, microdisplay, and automobile central control screens or tail lights.

Preferably, the disclosure provides an illumination or display device, which includes the organic electroluminescent device of the disclosure.

In addition, the disclosure also provides an electronic device, which includes an organic electroluminescent device as described above. The electronic device can be a mobile phone and can also be a computer, a television, an intelligent wearable device or the like. Specific limitation is not made by embodiments of the disclosure.

Next, the invention effects of this embodiment are compared and highlighted through examples and comparative examples.

### EXAMPLES

The compounds of the disclosure for the capping layer material used in examples can be compounds 1, 4, 5, 8, 12, 14, 18, 24, 28, 32, 34, 35, 37, 39, 42, 44, 45, 53 and 55 in the following compounds listed previously.

### Device Example 1

The following preparation steps are used to prepare an organic electroluminescent device, including:

A 7 nm ITO film (a first electrode layer 200) was formed on a low-temperature polycrystalline silicon (LTPS) substrate (substrate layer 100) in a manner of sputtering and etched into a required pattern. The ITO film was washed for 15 min with deionized water, acetone and ethanol respectively, and then treated for 2 min in a plasma washer. Here, the ITO electrode layer was an anode. The hole injection layer material HAT-CN was evaporated on the ITO anode layer through vacuum evaporation and has a thickness of 10 nm, and this layer was used as the hole injection layer 310; the hole transport material NPB was evaporated on the hole injection layer 310 through vacuum evaporation and has a thickness of 110 nm, and this layer was used as the hole transport layer 320 or a microcavity adjusting layer; an electronic barrier material TCTA was evaporated on the hole transport layer 320 through vacuum evaporation and has a thickness of 10 nm, and this layer was used as the electron barrier layer 330; a blue light-emitting layer 340 was evaporated on the electron barrier layer 330, CBP was used as a host material, BDAVBi was used as a doping material, the mass ratio of BDAVBi to CBP is 5:95, and the thickness was 20 nm; the electron transport material TPBI was evaporated on the light-emitting layer 340 through vacuum evaporation and has a thickness of 35 nm, and this organic material layer was used as the electron transport layer 360; an electron injection layer LiF was evaporated on the electron transport layer 360 and has a thickness of 1 nm, and this layer was the electron injection layer 370; a cathode Yb/Mg:Ag layer was evaporated in vacuum on the electron injection layer 370, the Yb thickness was 1 nm, the mass ratio of Mg to Ag was 1:9, the thickness was 14 nm, this layer was the second electrode layer 400, and this layer was a cathode layer; the material compound 1 in the example of the disclosure was evaporated on the second electrode layer 400 through vacuum evaporation and has a thickness of 50 nm, and this organic material layer was used as the capping layer 500.

### Device Example 2

The preparation manner is the same as that in device example 1, but the following device structure is adopted:

ITO (7 nm)/HAT-CN (10 nm)/NPB (150 nm)/TCTA (10 nm)/CBP:Ir(PPy)₃ (90:10 mass ratio, 90 mass % CBP) (40 nm)/TPBI (35 nm)/LiF (1 nm)/Yb (1 nm)/Mg:Ag (10:90 mass ratio, 10 mass % Mg) (14 nm)/compound 1 (50 nm) of the disclosure.

### Device Example 3

The preparation manner is the same as that in device example 1, but the following device structure is adopted:

ITO (7 nm)/HAT-CN (10 nm)/NPB (190 nm)/TCTA (10 nm)/CBP:Ir(pq)₂ acac (96:4 mass ratio, 96 mass % CBP) (40 nm)/TPBI (35 nm)/LiF (1 nm)/Yb (1 nm)/Mg:Ag (10:90 mass ratio, 10 mass % Mg) (14 nm)/compound 1 (50 nm) of the disclosure.

Device examples 4, 7, 10, 13, 16, 19, 22, 25, 28, 31, 34, 37, 40, 43, 46, 49, 52 and 55:

The preparation methods of device examples 4, 7, 10, 13, 16, 19, 22, 25, 28, 31, 34, 37, 40, 43, 46, 49, 52, 55 are the same as that in device example 1, and the difference lies in that compounds 4, 5, 8, 12, 14, 18, 24, 28, 32, 34, 35, 37, 39, 42, 44, 45, 53 and 55 are used as capping layer materials of the organic electroluminescent device.

Device examples 5, 8, 11, 14, 17, 20, 23, 26, 29, 32, 35, 38, 41, 44, 47, 50, 53 and 56:

The preparation method in device examples 5, 8, 11, 14, 17, 20, 23, 26, 29, 32, 35, 38, 41, 44, 47, 50, 53 and 56 are the same as that in device example 2 and the difference lies in that compounds 4, 5, 8, 12, 14, 18, 24, 28, 32, 34, 35, 37, 39, 42, 44, 45, 53 and 55 are used as the capping layer materials of the organic electroluminescent device.

Device examples 6, 9, 12, 15, 18, 21, 24, 27, 30, 33, 36, 39, 42, 45, 48, 51, 54 and 57:

The preparation methods in device examples 6, 9, 12, 15, 18, 21, 24, 27, 30, 33, 36, 39, 42, 45, 48, 51, 54 and 57 are the same as that in device example 3, and the difference lies in that compounds 4, 5, 8, 12, 14, 18, 24, 28, 32, 34, 35, 37, 39, 42, 44, 45, 53 and 55 are used as the capping layer materials of the organic electroluminescent device.

After preparation of the electroluminescent device is completed according to the above steps, current efficiency and perceptible chromatic aberration of the device are measured. The results are as shown in Table 2. Molecular structure formulas of relevant materials are as shown below:

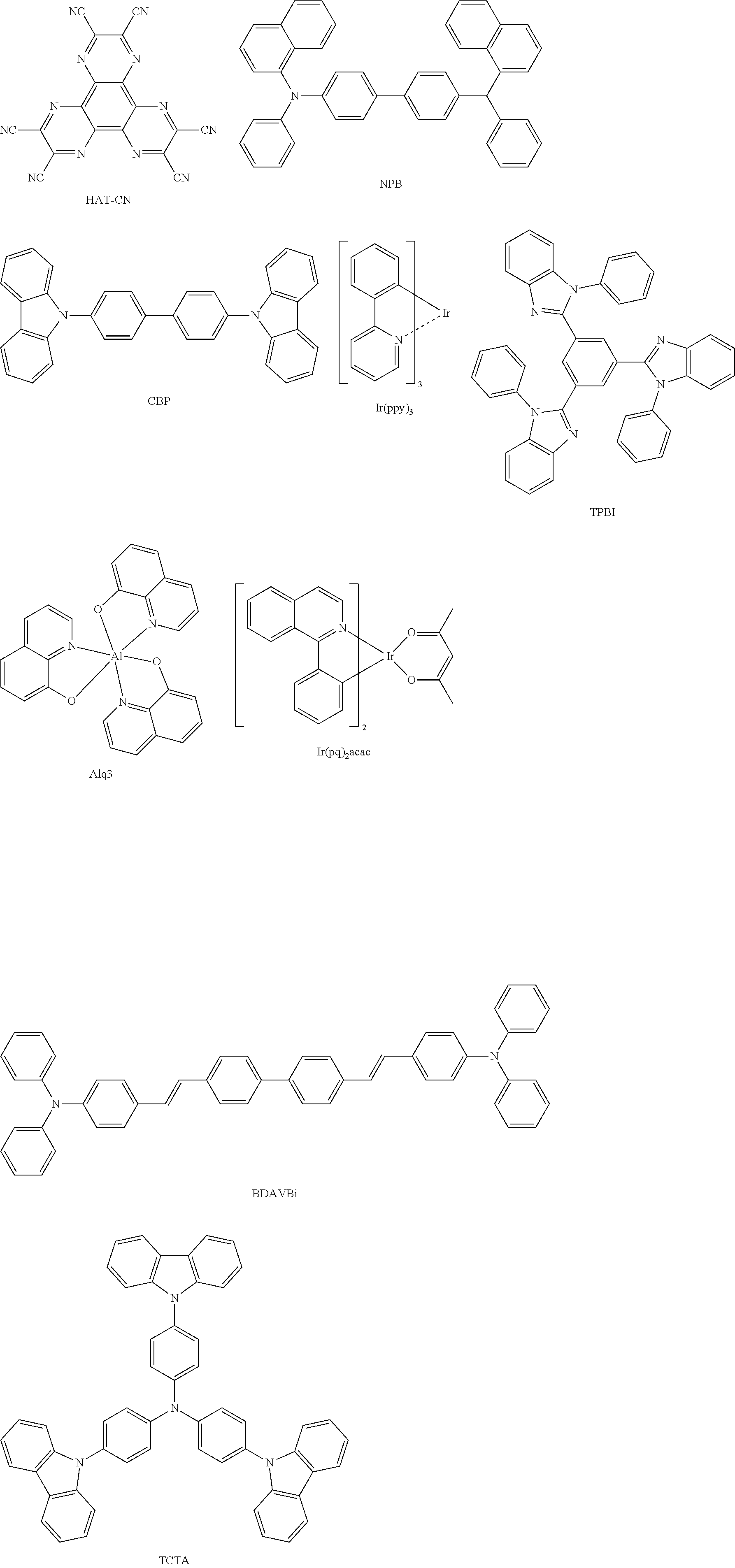

### Device Comparative Example 1

The preparation manner is the same as that in device example 1, but the following device structure is adopted:

ITO (7 nm)/HAT-CN (10 nm)/NPB (110 nm)/TCTA (10 nm)/CBP:BDAVBi (95:5 mass ratio, 95 mass % CBP) (40 nm)/TPBI (35 nm)/LiF (1 nm)/Yb (1 nm)/Mg:Ag (10:90 mass ratio, 10 mass % Mg) (14 nm)/Alq₃ (50 nm).

### Device Comparative Example 2

The preparation manner is the same as that in device example 1, but the following device structure is adopted:

ITO (7 nm)/HAT-CN (10 nm)/NPB (150 nm)/TCTA (10 nm)/CBP:Ir(PPy)₃ (90:10 mass ratio, 90 mass % CBP) (20 nm)/TPBI (35 nm)/LiF (1 nm)/Yb (1 nm)/Mg:Ag (10:90 mass ratio, 10 mass % Mg) (14 nm)/Alq₃ (50 nm).

### Device Comparative Example 3

The preparation manner is the same as that in device example 1, but the following device structure is adopted:

ITO (7 nm)/HAT-CN (10 nm)/NPB (190 nm)/TCTA (10 nm)/CBP:Ir(pq)₂acac (96:4 mass ratio, 96 mass % CBP) (40 nm)/TPBI (35 nm)/LiF (1 nm)/Yb (1 nm)/Mg:Ag (10:90 mass ratio, 10 mass % Mg) (14 nm)/Alq₃ (50 nm).

Measurement of Current Efficiency, CIE and Perceptible Chromatic Aberration

The current efficiency, CIEs and CIEy of the OLED devices in the above examples and comparative examples are measured using an IVL (current-voltage-brightness) test system ( [symbol] [symbol] (Nihon system giken Co., Ltd.)) and selecting software EILV20060707, and the following results are obtained.

TABLE 2

| | | | | Refractive | | | | |
|---|---|---|---|---|---|---|---|---|
| | | | | index of | Device data | | | |
| | | | | capping | Current | | | JNCD |
| Device code | Materials | Color | | layer | efficiency | CIEx | CIEy | @30° |
| Device | Compound | Blue | 450 nm | 2.209 | 109% | 0.144 | 0.041 | 0.020 |
| example 1 | 1 | | | | | | | |
| Device | | Green | 525 nm | 2.088 | 112% | 0.211 | 0.728 | 0.007 |
| example 2 | | | | | | | | |
| Device | | Red | 620 nm | 2.025 | 116% | 0.665 | 0.334 | 0.024 |
| example 3 | | | | | | | | |
| Device | Compound | Blue | 450 nm | 2.062 | 106% | 0.143 | 0.042 | 0.025 |
| example 4 | 4 | | | | | | | |
| Device | | Green | 525 nm | 1.968 | 108% | 0.217 | 0.727 | 0.009 |
| example 5 | | | | | | | | |
| Device | | Red | 620 nm | 1.916 | 111% | 0.665 | 0.334 | 0.025 |
| example 6 | | | | | | | | |
| Device | Compound | Blue | 450 nm | 1.925 | 103% | 0.142 | 0.044 | 0.029 |
| example 7 | 5 | | | | | | | |
| Device | | Green | 525 nm | 1.854 | 104% | 0.224 | 0.726 | 0.011 |
| example 8 | | | | | | | | |
| Device | | Red | 620 nm | 1.814 | 106% | 0.666 | 0.333 | 0.025 |
| example 9 | | | | | | | | |
| Device | Compound | Blue | 450 nm | 1.965 | 104% | 0.142 | 0.043 | 0.028 |
| example 10 | 8 | | | | | | | |
| Device | | Green | 525 nm | 1.842 | 104% | 0.224 | 0.726 | 0.011 |
| example 11 | | | | | | | | |
| Device | | Red | 620 nm | 1.79 | 104% | 0.666 | 0.333 | 0.025 |
| example 12 | | | | | | | | |
| Device | Compound | Blue | 450 nm | 1.974 | 104% | 0.142 | 0.043 | 0.028 |
| example 13 | 12 | | | | | | | |
| Device | | Green | 525 nm | 1.914 | 106% | 0.220 | 0.727 | 0.010 |
| example 14 | | | | | | | | |
| Device | | Red | 620 nm | 1.872 | 108% | 0.665 | 0.334 | 0.025 |
| example 15 | | | | | | | | |
| Device | Compound | Blue | 450 nm | 1.938 | 103% | 0.142 | 0.044 | 0.029 |
| example 16 | 14 | | | | | | | |
| Device | | Green | 525 nm | 1.862 | 104% | 0.223 | 0.726 | 0.011 |
| example 17 | | | | | | | | |
| Device | | Red | 620 nm | 1.822 | 106% | 0.666 | 0.333 | 0.025 |
| example 18 | | | | | | | | |
| Device | Compound | Blue | 450 nm | 2.204 | 109% | 0.144 | 0.041 | 0.020 |
| example 19 | 18 | | | | | | | |
| Device | | Green | 525nm | 2.119 | 113% | 0.209 | 0.728 | 0.006 |
| example 20 | | | | | | | | |
| Device | | Red | 620 nm | 2.063 | 118% | 0.665 | 0.334 | 0.024 |
| example 21 | | | | | | | | |
| Device | Compound | Blue | 450 nm | 1.92 | 103% | 0.142 | 0.044 | 0.029 |
| example 22 | 24 | | | | | | | |
| Device | | Green | 525nm | 1.854 | 104% | 0.224 | 0.726 | 0.011 |
| example 23 | | | | | | | | |
| Device | | Red | 620 nm | 1.818 | 106% | 0.666 | 0.333 | 0.025 |
| example 24 | | | | | | | | |
| Device | Compound | Blue | 450 nm | 1.886 | 102% | 0.142 | 0.044 | 0.031 |
| example 25 | 28 | | | | | | | |
| Device | | Green | 525nm | 1.836 | 103% | 0.224 | 0.726 | 0.011 |
| example 26 | | | | | | | | |
| Device | | Red | 620 nm | 1.805 | 105% | 0.666 | 0.333 | 0.025 |
| example 27 | | | | | | | | |
| Device | Compound | Blue | 450 nm | 1.945 | 103% | 0.142 | 0.043 | 0.029 |
| example 28 | 32 | | | | | | | |
| Device | | Green | 525nm | 1.859 | 104% | 0.223 | 0.726 | 0.011 |
| example 29 | | | | | | | | |
| Device | | Red | 620 nm | 1.818 | 106% | 0.666 | 0.333 | 0.025 |
| example 30 | | | | | | | | |
| Device | Compound | Blue | 450 nm | 2.206 | 109% | 0.144 | 0.041 | 0.020 |
| example 31 | 34 | | | | | | | |
| Device | | Green | 525 nm | 1.995 | 109% | 0.216 | 0.727 | 0.009 |
| example 32 | | | | | | | | |
| Device | | Red | 620 nm | 1.926 | 111% | 0.665 | 0.334 | 0.025 |
| example 33 | | | | | | | | |
| Device | Compound | Blue | 450 nm | 2.065 | 106% | 0.143 | 0.042 | 0.025 |
| example 34 | 35 | | | | | | | |
| Device | | Green | 525nm | 1.921 | 106% | 0.220 | 0.727 | 0.010 |
| example 35 | | | | | | | | |
| Device | | Red | 620 nm | 1.868 | 108% | 0.665 | 0.334 | 0.025 |
| example 36 | | | | | | | | |
| Device | Compound | Blue | 450 nm | 1.935 | 103% | 0.142 | 0.044 | 0.029 |
| example 37 | 37 | | | | | | | |
| Device | | Green | 525 nm | 1.877 | 105% | 0.222 | 0.726 | 0.011 |
| example 38 | | | | | | | | |
| Device | | Red | 620 nm | 1.842 | 107% | 0.666 | 0.333 | 0.025 |
| example 39 | | | | | | | | |
| Device | Compound | Blue | 450 nm | 1.871 | 102% | 0.142 | 0.044 | 0.031 |
| example 40 | 39 | | | | | | | |
| Device | | Green | 525 nm | 1.81 | 103% | 0.226 | 0.726 | 0.012 |
| example 41 | | | | | | | | |
| Device | | Red | 620 nm | 1.777 | 104% | 0.666 | 0.333 | 0.026 |
| example 42 | | | | | | | | |
| Device | Compound | Blue | 450 nm | 1.96 | 104% | 0.142 | 0.043 | 0.028 |
| example 43 | 42 | | | | | | | |
| Device | | Green | 525 nm | 1.897 | 106% | 0.221 | 0.726 | 0.010 |
| example 44 | | | | | | | | |
| Device | | Red | 620 nm | 1.822 | 106% | 0.666 | 0.333 | 0.025 |
| example 45 | | | | | | | | |
| Device | Compound | Blue | 450 nm | 1.913 | 103% | 0.142 | 0.044 | 0.030 |
| example 46 | 44 | | | | | | | |
| Device | | Green | 525 nm | 1.843 | 104% | 0.224 | 0.726 | 0.011 |
| example 47 | | | | | | | | |
| Device | | Red | 620 nm | 1.784 | 104% | 0.666 | 0.333 | 0.025 |
| example 48 | | | | | | | | |
| Device | Compound | Blue | 450 nm | 2.187 | 109% | 0.144 | 0.041 | 0.021 |
| example 49 | 45 | | | | | | | |
| Device | | Green | 525 nm | 2.078 | 112% | 0.212 | 0.728 | 0.007 |
| example 50 | | | | | | | | |
| Device | | Red | 620 nm | 2.016 | 116% | 0.665 | 0.334 | 0.024 |
| example 51 | | | | | | | | |
| Device | Compound | Blue | 450 nm | 2.093 | 107% | 0.143 | 0.042 | 0.024 |
| example 52 | 53 | | | | | | | |
| [symbol] | | Green | 525 nm | 2.009 | 109% | 0.215 | 0.727 | 0.008 |
| 53 | | | | | | | | |
| Device | | Red | 620 nm | 1.957 | 113% | 0.665 | 0.334 | 0.024 |
| example 54 | | | | | | | | |
| Device | Compound | Blue | 450 nm | 2.077 | 106% | 0.143 | 0.042 | 0.024 |
| example 55 | 55 | | | | | | | |
| Device | | Green | 525 nm | 2.012 | 109% | 0.215 | 0.727 | 0.008 |
| example 56 | | | | | | | | |
| Device | | Red | 620 nm | 1.97 | 113% | 0.665 | 0.334 | 0.024 |
| example 57 | | | | | | | | |
| Device | Alq | Blue | 450 nm | 1.780 | 100% | 0.141 | 0.045 | 0.034 |
| comparative | | | | | | | | |
| example 1 | | | | | | | | |
| Device | | Green | 525 nm | 1.733 | 100% | 0.230 | 0.725 | 0.013 |
| comparative | | | | | | | | |
| example 2 | | | | | | | | |
| Device | | Red | 620 nm | 1.702 | 100% | 0.666 | 0.333 | 0.026 |
| comparative | | | | | | | | |
| example 3 | | | | | | | | |

INCD, perceptible chromatic aberration. It should be understood that the small the perceptible chromatic aberration is, the small the chroma variation is, which means that the angle dependence of the emergent light wavelength of the organic electroluminescent device is better restricted.

It can be seen from Table 2 that:

Compared with comparative examples, the organic electroluminescent device prepared by the capping layer made of the compound of the disclosure has significantly improved current efficiency in the fields of blue light, green light and red light, thereby correspondingly improving the light extraction efficiency.

Compared with comparative examples, the organic electroluminescent device prepared by the capping layer made of the compound of the disclosure has smaller perceptible chromatic aberration in the fields of blue light, green light and red light, and therefore the angle dependence is smaller.

We claim:

1. An organic electroluminescent device, the organic electroluminescent device comprising:
a substrate layer;
a first electrode, the first electrode being located on the substrate;
an organic light-emitting functional layer, the organic light-emitting functional layer being located on the first electrode;
a second electrode, the second electrode being located on the organic light-emitting functional layer; and
a capping layer, the capping layer being located on the side of the organic electroluminescent device where light is emitted,
wherein, the capping layer comprises an organic compound,
the organic compound of the capping layer has the following properties:
having a molecular weight falling within the range from 500 to 1200 and containing lone pair electrons, the number of the lone pair electrons being greater than or equal to 2.

2. The organic electroluminescent device according to claim 1, wherein in the organic compound of the capping layer, an atom having the lone pair electrons is one or more of N, O and S atoms.

3. The organic electroluminescent device according to claim 1, wherein in the organic compound of the capping layer, the atom containing the lone pair electrons is bonded by SP2 hybrid orbit.

4. The organic electroluminescent device according to claim 1, wherein in the organic compound of the capping layer, a group containing the lone pair electrons is one or more of the following groups: groups of pyridine, pyrazine, pyridazine, pyrimidine, triazine, quinoline, isoquinoline, quinoxaline, quinazoline, cinnoline, 2,3-diazanaphthalene, naphthyridine, benzimidazole, benzoxazole, phenanthroline, azatriphenylene, indolylpyridine, acridine, pyrazol, oxadiazole, triazole, pyrazolone, imidazole, imidazolone, ketone, ether or sulfoxide.

5. The organic electroluminescent device according to claim 1, wherein the refractive index of the organic compound of the capping layer in a blue wavelength region is 1.8 or more, preferably 2.0 or more, more preferably 2.0-2.4; the refractive index of the organic compound of the capping layer in a green wavelength region is 1.8 or more, preferably 1.9 or more, more preferably 1.9-2.2; the refractive index of the organic compound of the capping layer in a red wavelength region is 1.7 or more, preferably 1.8 or more, more preferably 1.8-2.1.

6. The organic electroluminescent device according to claim 1, wherein the extinction coefficient of the organic compound of the capping layer is 0.1 or less within a range of 380 nm-780 nm.

7. The organic electroluminescent device according to claim 1, wherein the molecular weight of the organic compound of the capping layer is 500-1100, preferably 600-1000, more preferably 600-850.

8. The organic electroluminescent device according to claim 1, wherein the number of the lone pair electrons of the organic compound of the capping layer is 3-15, preferably 3-9.

9. The organic electroluminescent device according to claim 1, wherein the capping layer is a singe layer or multiple layers.

10. The organic electroluminescent device according to claim 1, wherein the capping layer is formed by using two or more material layers having different refractive indexes, and two layers or multiple layers are formed by alternately overlapping a material layer having a relatively high refractive index with a material layer having a relatively low refractive index.

11. The organic electroluminescent device according to claim 1, wherein the organic compound of the capping layer has no absorption in a region of 440˜650 nm.

12. The organic electroluminescent device according to claim 1, wherein the organic compound of the capping layer is represented by general formula (1): 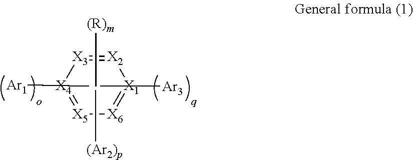
wherein, X₁˜X₆ each independently represent N atom, C atom or CH, wherein the number of N atoms is 1-4;
o, p and q independently represents the number 0, 1, 2 or 3, respectively, and 0≤o+p+q≤4;
m represents the number 0, 1, 2 or 3, and 0≤o+p+q+m≤4;
Ar₁, Ar₂ and Ar₃ are independently identical or different in each case, and are independently expressed as the structure shown in general formula (2) respectively:
—L—R₁ General formula (2)
wherein, L represents a single bond, substituted or unsubstituted C₆₋₆₀ arylidene, substituted or unsubstituted 5-60-membered heteroarylidene containing one or more heteroatoms, wherein the heteroatom is nitrogen, oxygen or sulfur;
R₁ represents one of groups of benzimidazole and derivatives, quinoxaline and derivatives, benzoxazole and derivatives, and naphthyridine and derivatives;
R represents substituted or unsubstituted C₆₋₆₀ aryl, substituted or unsubstituted 5-60-membered heteroaryl containing one or more heteroatoms, wherein the heteroatom is nitrogen, oxygen or sulfur.

13. The organic electroluminescent device according to claim 12, wherein L in general formula (2) represents phenylene, biphenylene, naphthylene, pyridinediyl or naphthylidene substituted or unsubstituted by C₁₋₁₀ linear or branched alkyl, halogen atoms, protium atom, deuterium atom or tritium atom;
In general formula (1), R represents one of phenyl substituted or unsubstituted by C₁₋₁₀ linear or branched alkyl, halogen atoms, protium atom, deuterium atom or tritium atom; naphthyl substituted or unsubstituted by C₁₋₁₀ linear or branched alkyl, halogen atoms, protium atom, deuterium atom or tritium atom; biphenyl, triphenyl or anthryl substituted or unsubstituted by C₁₋₁₀ linear or branched alkyl, halogen atoms, protium atom, deuterium atom or tritium atom; pyridyl, pyrimidinyl, pyrazinyl, pyridazinyl, dibenzofuran, 9,9-dimethylfluorene, N-phenylcarbazole, quinolinyl, isoquinolinyl or naphthyridine group substituted or unsubstituted by C₁₋₁₀ linear or branched alkyl, halogen atoms, protium atom, deuterium atom or tritium atom; R is also expressed as a structure shown in general formula (3), general formula (4) or general formula (5); 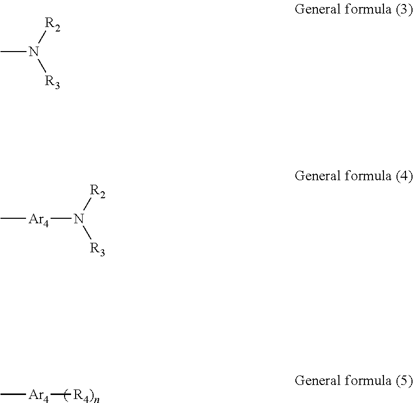
Ar₄ in general formula (4) and general formula (5) independently represent one of phenyl substituted or unsubstituted by C₁₋₁₀ linear or branched alkyl, halogen atoms, protium atom, deuterium atom or tritium atom; naphthyl substituted or unsubstituted by C₁₋₁₀ linear or branched alkyl, halogen atoms, protium atom, deuterium atom or tritium atom; biphenyl, triphenyl or anthryl substituted or unsubstituted by C₁₋₁₀ linear or branched alkyl, halogen atoms, protium atom, deuterium atom or tritium atom; pyridyl, pyrimidinyl, pyrazinyl, pyridazinyl, dibenzofuran, 9,9-dimethylfluorene, N-phenylcarbazole, quinolinyl, isoquinolinyl or naphthyridine group substituted or unsubstituted by C₁₋₁₀ linear or branched alkyl, halogen atoms, protium atom, deuterium atom or tritium atom, respectively;
in general formula (3), general formula (4) and general formula (5), R₂, R₃ and R₄ independently represent one of phenyl substituted or unsubstituted by C₁₋₁₀ linear or branched alkyl, halogen atoms, protium atom, deuterium atom or tritium atom; naphthyl substituted or unsubstituted by C₁₋₁₀ linear or branched alkyl, halogen atoms, protium atom, deuterium atom or tritium atom; spirobifluorene group substituted or unsubstituted by C₁₋₁₀ linear or branched alkyl, halogen atoms, protium atom, deuterium atom or tritium atom; biphenyl, triphenyl or anthryl substituted or unsubstituted by C₁₋₁₀ linear or branched alkyl, halogen atoms, protium atom, deuterium atom or tritium atom; pyridyl, pyrimidinyl, pyrazinyl, pyridazinyl, dibenzofuran, 9,9-dimethylfluorene, N-phenylcarbazole, quinolinyl, isoquinolinyl or naphthyridine group substituted or unsubstituted by C₁₋₁₀ linear or branched alkyl, halogen atoms, protium atom, deuterium atom or tritium atom, respectively;
R₂, R₃ and R₄ are identical or different;
in general formula (5), n represents an integer 1 or 2.

14. The organic electroluminescent device according to claim 1, wherein the organic compound of the capping layer is 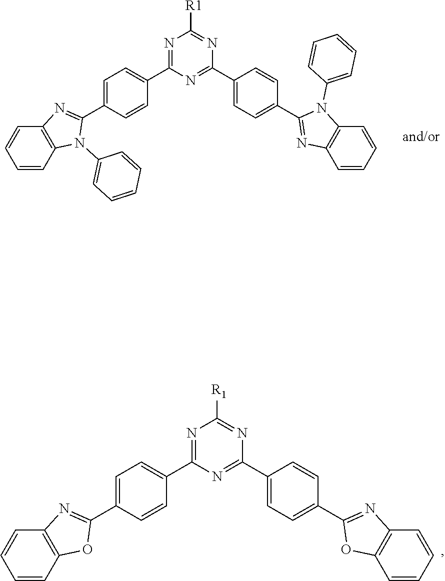
wherein R1 is selected from biphenylyl, naphtyl, biphenylyl, N-phenylcarbazolyl or

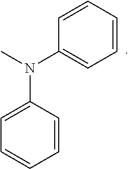

15. The organic electroluminescent device according to claim 1, wherein the organic compound of the capping layer is 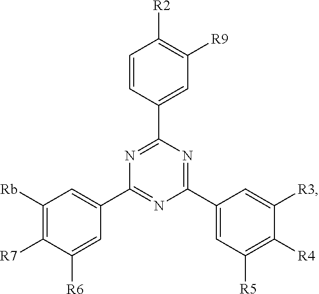
wherein R2 is selected from H, C1-6 alkyl, pyridyl, pyrimidyl, 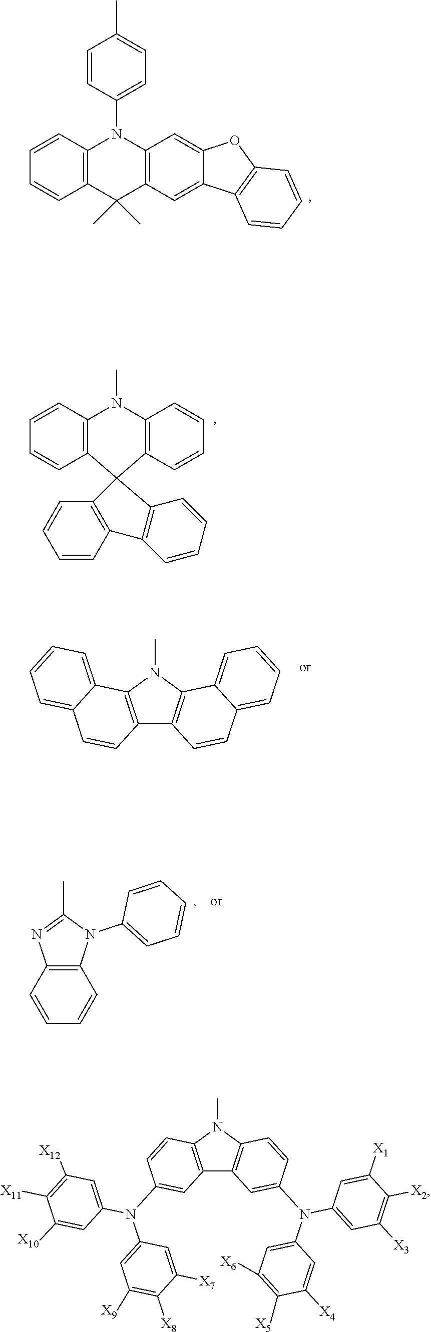
wherein
X1, X2, X3, X4, X5, X6, X7, X8, X9, X10, X11 and X12 are each independently hydrogen or C1-C6 alkyl, preferably hydrogen, methyl or tert-butyl;
R3, R4, R5, R6, R7 and R8 are each independently selected from hydrogen, C1-C6 alkyl, pyridyl, pyrimidyl, 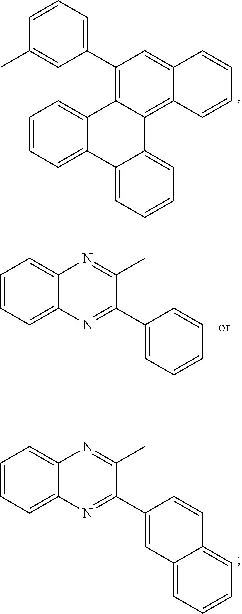
R9 is selected from H, C1-C6 alkyl, pyrimidyl, pyridyl,

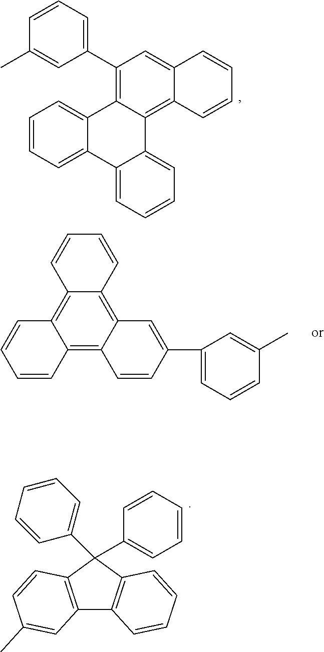

16. The organic electroluminescent device according to claim 1, wherein the organic compound of the capping layer is 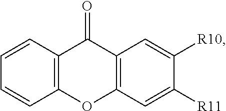
wherein R10 and R11 are each independently selected from 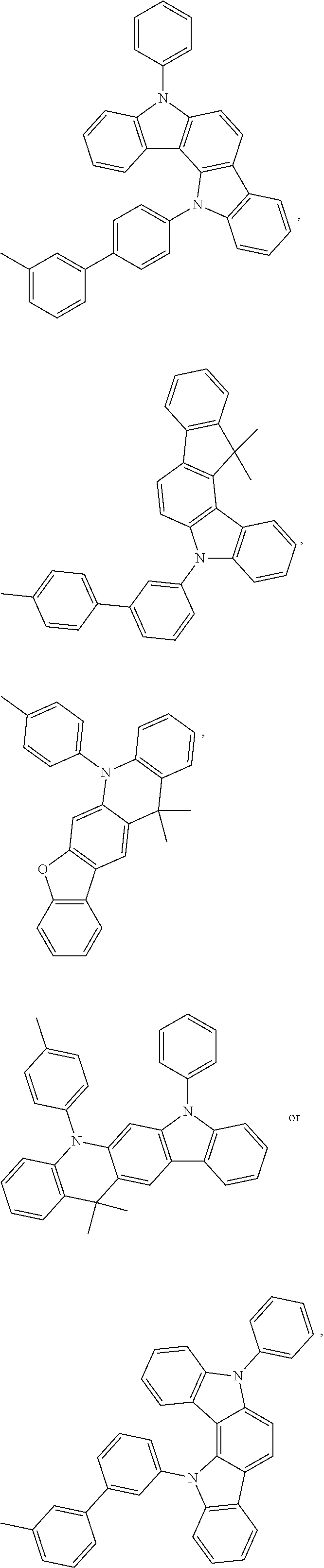 [SMILES: Cc1cccc(-c2ccc(-n3c4ccccc4c4ccc5c(c6ccccc6n5-c5ccccc5)c43)cc2)c1 ; Cc1ccc(-c2cccc(-n3c4ccccc4c4c5c(ccc43)-c3ccccc3C5(C)C)c2)cc1 ; Cc1ccc(N2c3ccccc3C(C)(C)c3cc4c(cc32)oc2ccccc24)cc1 ; Cc1ccc(N2c3ccccc3C(C)(C)c3cc4c5ccccc5n(-c5ccccc5)c4cc32)cc1 ; Cc1cccc(-c2cccc(-n3c4ccccc4c4ccc5c(c6ccccc6n5-c5ccccc5)c43)c2)c1]
or selected from 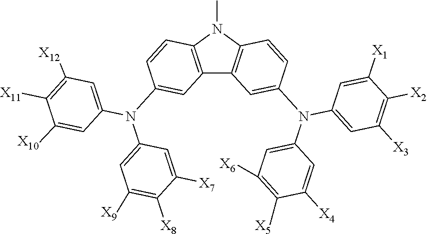
wherein, X1, X2, X3, X4, X5, X6, X7, X8, X9, X10, X11 and X12 are each independently hydrogen or C1-C6 alkyl, preferably hydrogen, methyl or tert-butyl.

17. The organic electroluminescent device according to claim 1, wherein the organic compound of the capping layer is 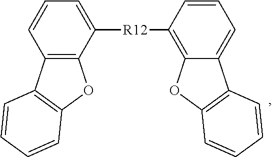
wherein R12 is selected from

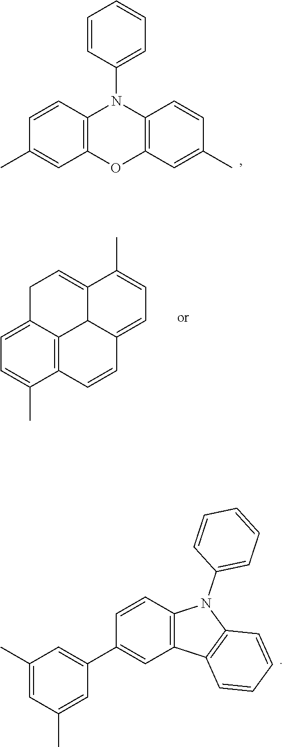

18. The organic electroluminescent device according to claim 1, wherein the organic compound of the capping layer is one or more of the following compounds:

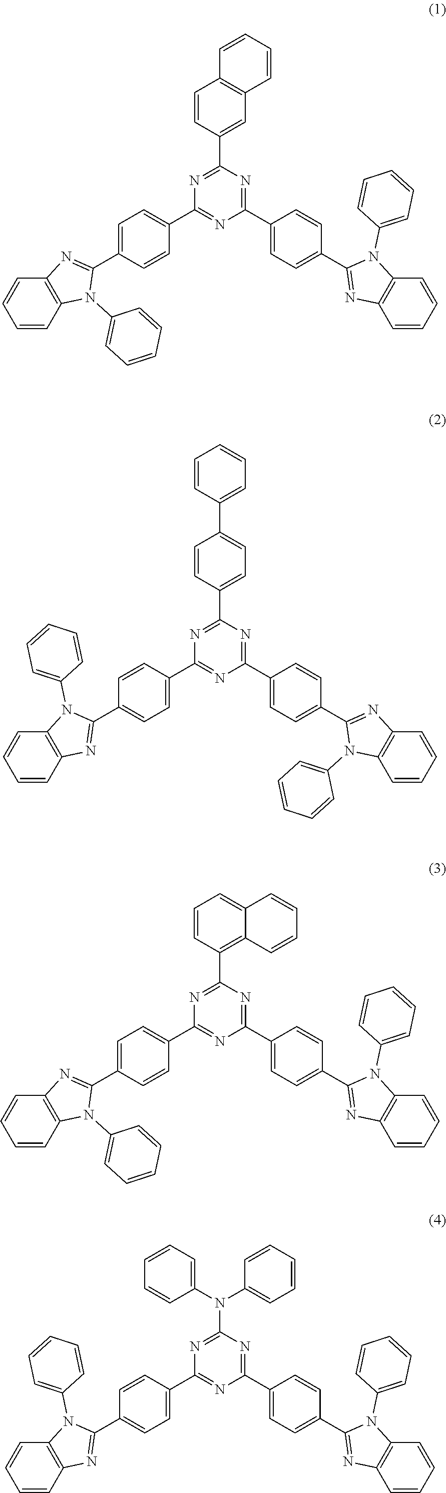 [SMILES: c1ccc(-n2c(-c3ccc(-c4nc(-c5ccc(-c6nc7ccccc7n6-c6ccccc6)cc5)nc(-c5ccc6ccccc6c5)n4)cc3)nc3ccccc32)cc1 ; c1ccc(-c2ccc(-c3nc(-c4ccc(-c5nc6ccccc6n5-c5ccccc5)cc4)nc(-c4ccc(-c5nc6ccccc6n5-c5ccccc5)cc4)n3)cc2)cc1 ; c1ccc(-n2c(-c3ccc(-c4nc(-c5ccc(-c6nc7ccccc7n6-c6ccccc6)cc5)nc(-c5cccc6ccccc56)n4)cc3)nc3ccccc32)cc1 ; c1ccc(N(c2ccccc2)c2nc(-c3ccc(-c4nc5ccccc5n4-c4ccccc4)cc3)nc(-c3ccc(-c4nc5ccccc5n4-c4ccccc4)cc3)n2)cc1]

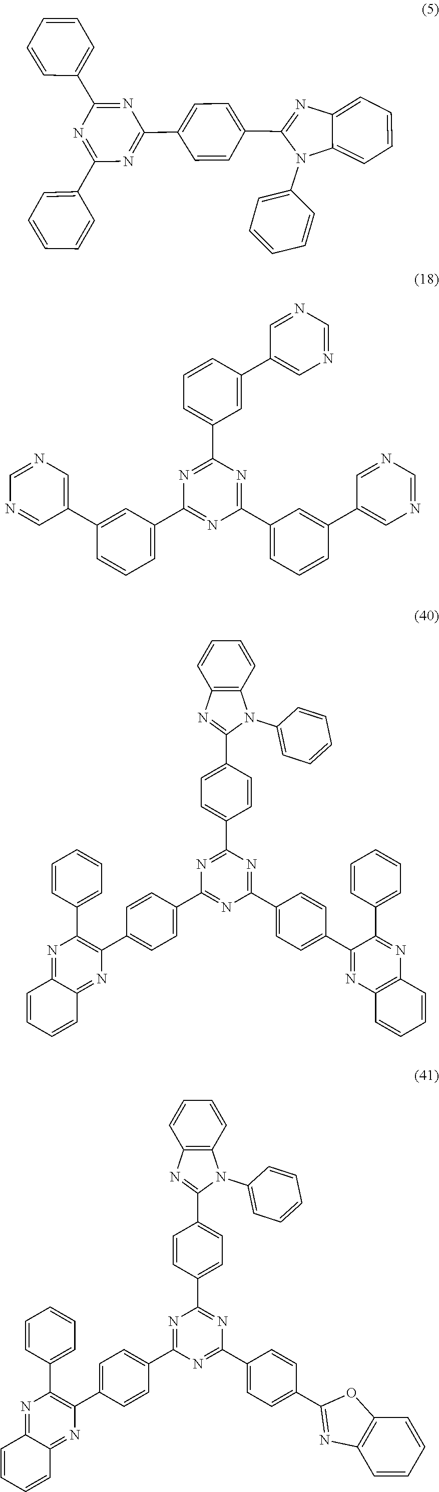 [SMILES: c1ccc(-c2nc(-c3ccccc3)nc(-c3ccc(-c4nc5ccccc5n4-c4ccccc4)cc3)n2)cc1 ; c1cc(-c2cncnc2)cc(-c2nc(-c3cccc(-c4cncnc4)c3)nc(-c3cccc(-c4cncnc4)c3)n2)c1 ; c1ccc(-c2nc3ccccc3nc2-c2ccc(-c3nc(-c4ccc(-c5nc6ccccc6nc5-c5ccccc5)cc4)nc(-c4ccc(-c5nc6ccccc6n5-c5ccccc5)cc4)n3)cc2)cc1 ; c1ccc(-c2nc3ccccc3nc2-c2ccc(-c3nc(-c4ccc(-c5nc6ccccc6o5)cc4)nc(-c4ccc(-c5nc6ccccc6n5-c5ccccc5)cc4)n3)cc2)cc1]

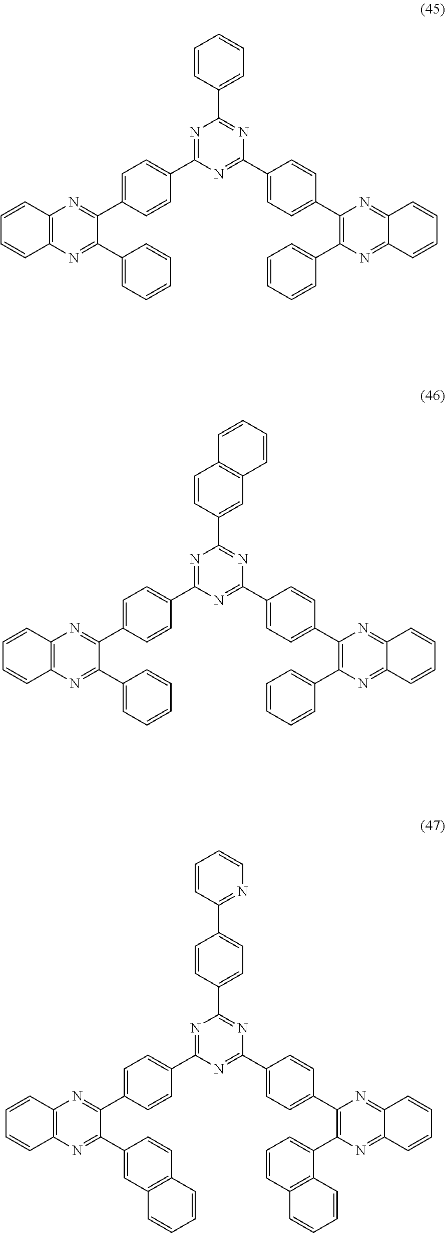 [SMILES: c1ccc(-c2nc(-c3ccc(-c4nc5ccccc5nc4-c4ccccc4)cc3)nc(-c3ccc(-c4nc5ccccc5nc4-c4ccccc4)cc3)n2)cc1 ; c1ccc(-c2nc3ccccc3nc2-c2ccc(-c3nc(-c4ccc(-c5nc6ccccc6nc5-c5ccccc5)cc4)nc(-c4ccc5ccccc5c4)n3)cc2)cc1 ; c1ccc(-c2ccc(-c3nc(-c4ccc(-c5nc6ccccc6nc5-c5ccc6ccccc6c5)cc4)nc(-c4ccc(-c5nc6ccccc6nc5-c5cccc6ccccc56)cc4)n3)cc2)nc1]

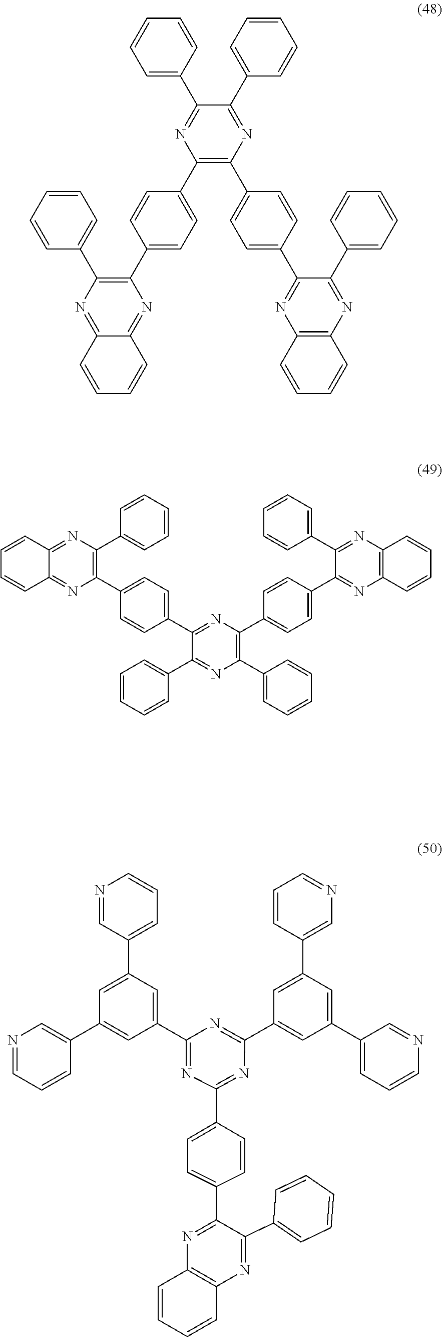 [SMILES: c1ccc(-c2nc(-c3ccc(-c4nc5ccccc5nc4-c4ccccc4)cc3)c(-c3ccc(-c4nc5ccccc5nc4-c4ccccc4)cc3)nc2-c2ccccc2)cc1 ; c1ccc(-c2nc(-c3ccccc3)c(-c3ccc(-c4nc5ccccc5nc4-c4ccccc4)cc3)nc2-c2ccc(-c3nc4ccccc4nc3-c3ccccc3)cc2)cc1 ; c1ccc(-c2nc3ccccc3nc2-c2ccc(-c3nc(-c4cc(-c5cccnc5)cc(-c5cccnc5)c4)nc(-c4cc(-c5cccnc5)cc(-c5cccnc5)c4)n3)cc2)cc1]

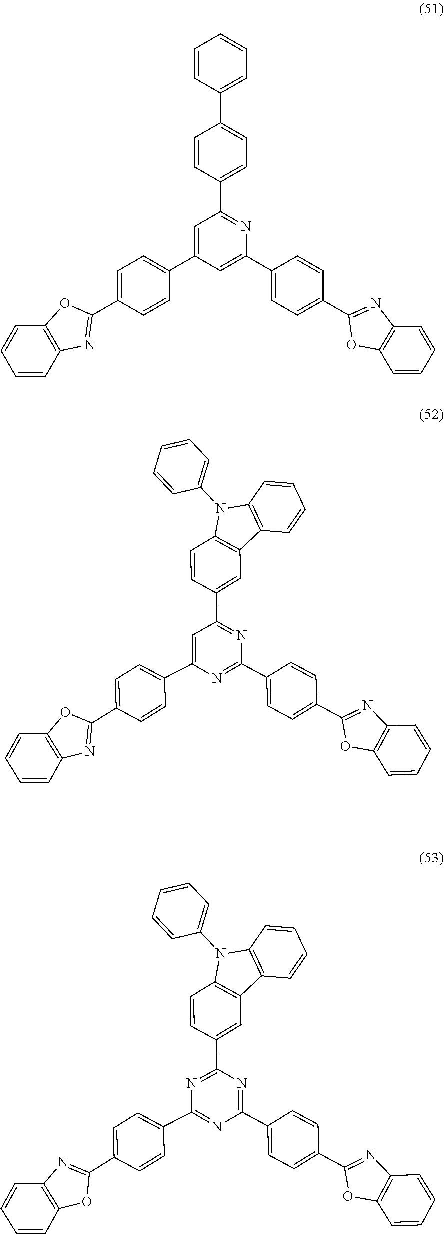 [SMILES: c1ccc(-c2ccc(-c3cc(-c4ccc(-c5nc6ccccc6o5)cc4)cc(-c4ccc(-c5nc6ccccc6o5)cc4)n3)cc2)cc1 ; c1ccc(-n2c3ccccc3c3cc(-c4cc(-c5ccc(-c6nc7ccccc7o6)cc5)nc(-c5ccc(-c6nc7ccccc7o6)cc5)n4)ccc32)cc1 ; c1ccc(-n2c3ccccc3c3cc(-c4nc(-c5ccc(-c6nc7ccccc7o6)cc5)nc(-c5ccc(-c6nc7ccccc7o6)cc5)n4)ccc32)cc1]

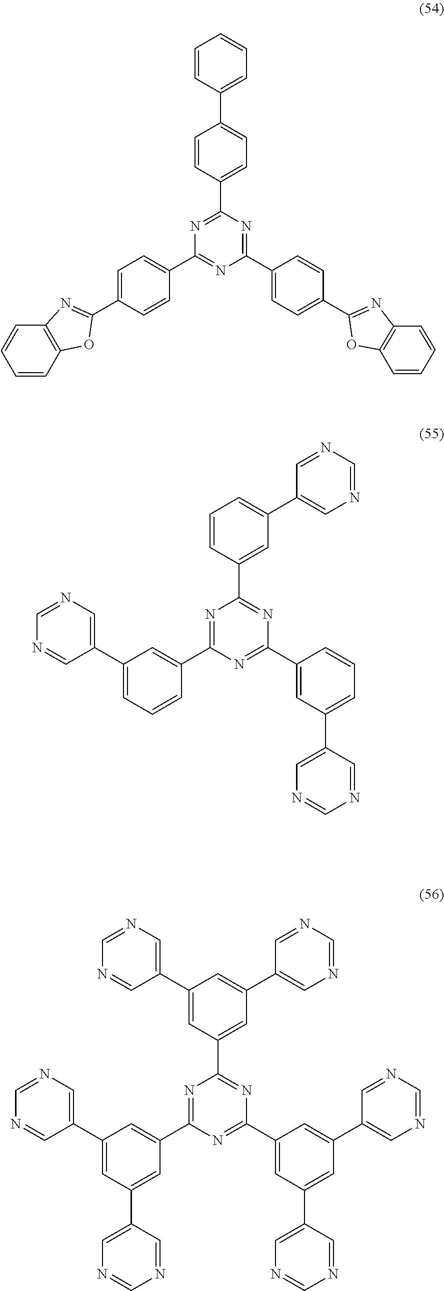 [SMILES: c1ccc(-c2ccc(-c3nc(-c4ccc(-c5nc6ccccc6o5)cc4)nc(-c4ccc(-c5nc6ccccc6o5)cc4)n3)cc2)cc1 ; c1cc(-c2cncnc2)cc(-c2nc(-c3cccc(-c4cncnc4)c3)nc(-c3cccc(-c4cncnc4)c3)n2)c1 ; c1ncc(-c2cc(-c3cncnc3)cc(-c3nc(-c4cc(-c5cncnc5)cc(-c5cncnc5)c4)nc(-c4cc(-c5cncnc5)cc(-c5cncnc5)c4)n3)c2)cn1]

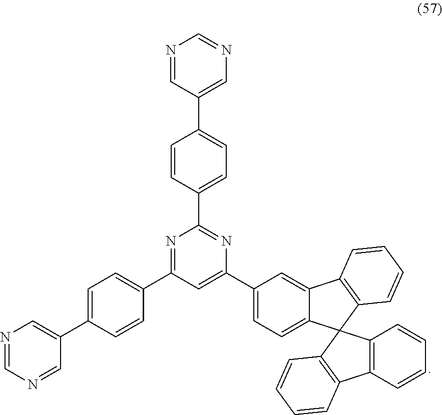 [SMILES: c1ccc2c(c1)-c1ccccc1C21c2ccccc2-c2cc(-c3cc(-c4ccc(-c5cncnc5)cc4)nc(-c4ccc(-c5cncnc5)cc4)n3)ccc21]

19. The organic electroluminescent device according to claim 1, wherein the organic light-emitting functional layer comprises a light-emitting layer, the light-emitting layer comprising one or a combination of at least two of a blue light-emitting pixel, a green light-emitting pixel, a red light-emitting pixel and a yellow light-emitting pixel.

20. The organic electroluminescent device according to claim 1, wherein the organic light-emitting functional layer and capping layer materials are formed through evaporation, spin coating, ink-jet printing or silk-screen printing.
